(19) United States
(12) Patent Application Publication
(10) Pub. No.: US 2026/0096160 A1
(43) Pub. Date: Apr. 2, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Sean MA, Hsinchu (TW); Zhiqiang WU, Hsinchu (TW); Shu-Hua WU, Hsinchu (TW); Shih-Syuan HUANG, Hsinchu (TW); Wen-Hsing HSIEH, Hsinchu (TW)

(73) Assignee: Taiwan Semiconductor Manufacturing Company, Ltd., Hsinchu (TW)

(21) Appl. No.: 18/903,736

(22) Filed: Oct. 1, 2024

(51) Int. Cl. H01L 29/06; H01L 29/423; H01L 29/66; H01L 29/775; H01L 29/786

(52) U.S. Cl. CPC H10D 62/121; H10D 30/014; H10D 30/43; H10D 30/6735; H10D 30/6755; H10D 30/6757; H10D 64/018

(57) ABSTRACT

A semiconductor structure includes a substrate, an active channel sheet and a doping layer. The active channel sheet stacked on the substrate, wherein the active channel sheet has an end portion having a lateral surface, an upper surface and a lower surface. The doping layer is disposed within the end portion of the active channel sheet. The doping layer has a contour having an upper point adjacent to the upper surface, a lower point adjacent to the lower surface and a middle point between the upper point and the lower point, there is an upper distance between the upper point and the lateral surface, there is a lower distance between the lower point and the lateral surface, there is a middle distance between the middle point and the lateral surface, and the upper distance and the lower distance are less than the middle distance.

### BACKGROUND

In a conventional manufacturing process of NS (nano-sheet) GAA (gate-all-around) transistor, an end portion of the active channel sheet is removed, and the epitaxial S/D (source/drain) fills the removed portion of the active channel sheet. However, such process is easy to cause some problem. For example, an edge of the epitaxial S/D adjacent to an inner spacer has a lower concentration than that of a center of the epitaxial S/D (it causes the poor gate control), and a current leakage is easy to occur due to the length of the active channel sheet is shorten.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1_a illustrates a schematic diagram of a cross-sectional view of a local portion of a semiconductor structure along a X-Z plane according to an embodiment of the present disclosure;

FIG. 1_b illustrates a schematic diagram of a cross-sectional view of the local portion of the semiconductor structure along a Y-Z plane;

FIG. 1_c illustrates a schematic diagram of a The relationship between a doping concentration and height positions of the active channel sheet;

FIG. 2_a illustrates a schematic diagram of a cross-sectional view of a local portion of a semiconductor structure along a X-Z plane according to an embodiment of the present disclosure;

FIG. 2_b illustrates a schematic diagram of a cross-sectional view of the local portion of the semiconductor structure along a Y-Z plane;

FIG. 3_a illustrates a schematic diagram of a cross-sectional view of a local portion of a semiconductor structure along a X-Z plane according to an embodiment of the present disclosure;

FIG. 3_b illustrates a schematic diagram of a cross-sectional view of the local portion of the semiconductor structure along a Y-Z plane;

FIGS. 4A_a to 4O_b illustrate schematic diagrams of manufacturing processes of the semiconductor structure 100 in FIGS. 1_a to 1_b;

FIGS. 5A_a to 5M_b illustrate schematic diagrams of manufacturing processes of the semiconductor structure in FIGS. 2_a to 2_b; and

FIGS. 6A_a to 6M_b illustrate schematic diagrams of manufacturing processes of the semiconductor structure in FIGS. 3_a to 3_b.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

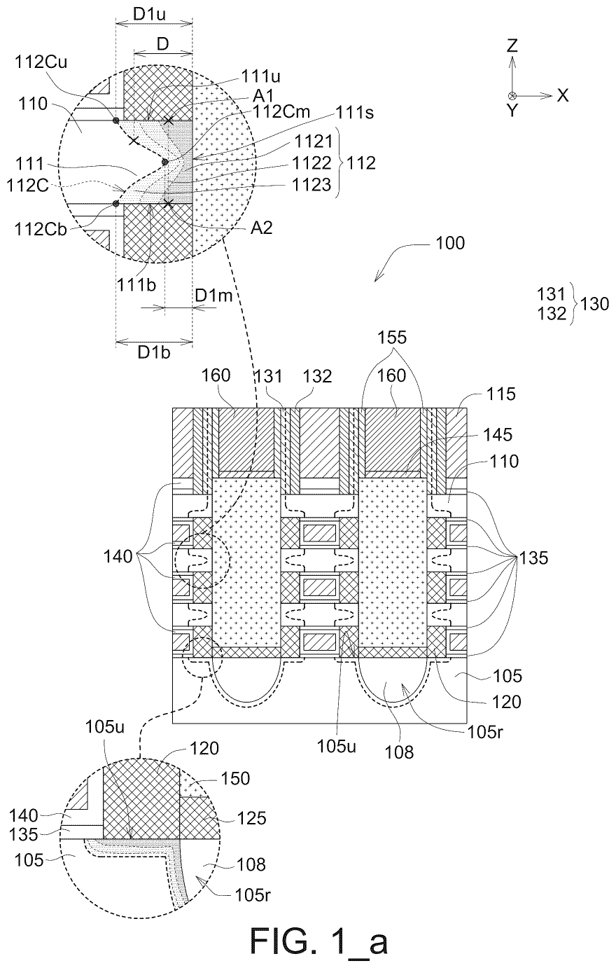

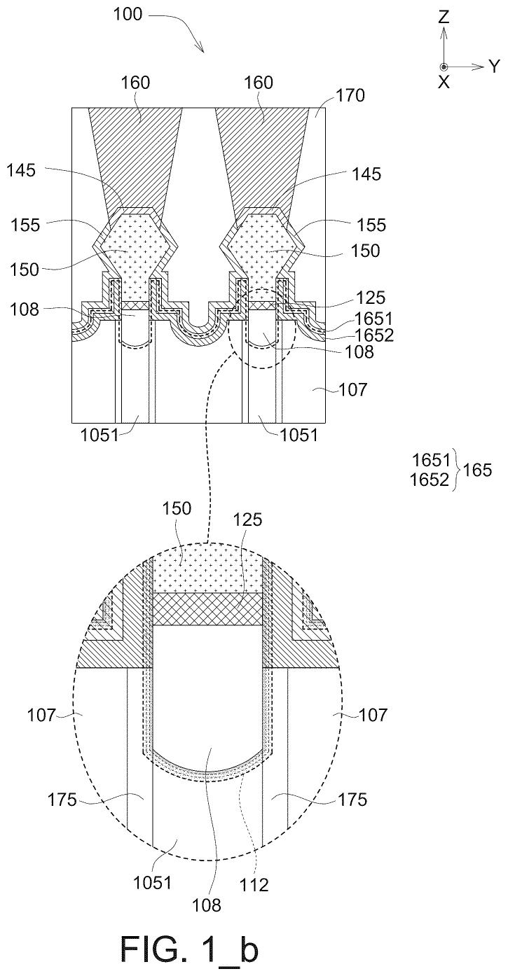

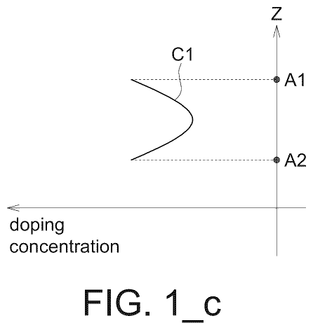

As illustrated in FIGS. 1_a to 1_c, FIG. 1_a illustrates a schematic diagram of a cross-sectional view of a local portion of a semiconductor structure 100 along a X-Z plane according to an embodiment of the present disclosure, FIG. 1_b illustrates a schematic diagram of a cross-sectional view of the local portion of the semiconductor structure 100 along a Y-Z plane, and FIG. 1_c illustrates a schematic diagram of a The relationship between a doping concentration and height positions of the active channel sheet 110.

As illustrated in FIGS. 1_a and 1_b, the semiconductor structure 100 includes a substrate 105, an oxide layer 107, a silicon epitaxy 108, a plurality of active channel sheets 110, at least one doping layer 112, a plurality of metal gate 115, a plurality of inner spacer 120, a plurality of isolation layers 125, a plurality of first spacers 130, a plurality of first dielectric layers 135, a plurality of second dielectric layers 140, a plurality of silicide layers 145, a plurality of epitaxies 150, a plurality of contact etching stop layers (CESLs) 155, a plurality of contacts 160, a plurality of second spacers 165, an interlayer dielectric (ILD) 170 and a plurality of liners 175.

As illustrated in FIGS. 1_a to 1_b, the active channel sheet 110 are stacked on the substrate 105 in a direction Z, wherein the active channel sheet 110 has an end portion 111 having a lateral surface 111s, an upper surface 111u and a lower surface 111b. The doping layer 112 is disposed within the end portion 111 of the active channel sheet 110. The doping layer 112 has a contour 112C having an upper point 112Cu adjacent to the upper surface 111u, a lower point 112Cb adjacent to the lower surface 111b and a middle point 112Cm between the upper point 112Cu and the lower point 112Cb, there is an upper distance D1u between the upper point 112Cu and the lateral surface 111s, there is a lower distance D1b between the lower point 112Cb and the lateral surface 111s, there is a middle distance D1mbetween the middle point 112Cm and the lateral surface 111s, and the upper distance D1u and the lower distance D1b are more than the middle distance D1m. Due the design of the contour 112C, the gate may gain better control over the channel.

As illustrated in FIG. 1_a, there is a contour distance D between the contour 112C and the lateral surface 111s of the active channel sheet 110, the contour distance D gradually decreases from the upper surface 111u toward the middle point 112Cm between the upper surface 111u and the lower surface 111b, and gradually increase from the middle point 112Cm toward the lower surface 111b.

As illustrated in FIG. 1_a, the doping layer 112 includes a plurality of doping regions (for example, 1121, 1122 and 1123) which have different concentrations. The doping regions 1121, 1122 and 1123 are distributed from outside to inside, wherein the doping concentration of the doping region 1121 is greater than that of the doping region 1122, and the doping concentration of the doping region 1122 is greater than that of the doping region 1123.

As illustrated in FIG. 1_c, a curve C1 shows that a variety of the doping concentration in a position between a point A1 and a point A2 along the Z direction. The doping layer 112 has a doping concentration distribution. The doping concentration distribution gradually decreases from outside to inside. For example, for the active channel sheet 110, the doping concentration distribution gradually decreases from the upper surface 111u toward the middle point 112Cm between the upper surface 111u and the lower surface 111b, and gradually increases from the middle point 112Cm toward the lower surface 111b.

In an embodiment, the doping layer 112 includes boron or phosphorus. In an embodiment, the doping layer 112 may be formed by a doped film with high concentration, for example, a BSG (boro-silicate glass) film or a PSG (phospho-silicate glass) film. The BSG film has a boron concentration of 2×10¹⁹cm⁻³¿5×10²¹cm⁻³, and the PSG film has a phosphorus concentration of 2×10¹⁹cm⁻³¿5×10²¹cm⁻³. The concentration of the BSG film and the concentration of the PSG film may be the same or different. The doping layer 112 may form a semiconductor layer with a component including silicon (for example, the substrate 105 and the active channel sheet 110). Due to the doping layer 112 being formed by the doped film, the end portion of the active channel sheet 110 is not required to be removed for filling epitaxial material. Due to the end portion of the active channel sheet 110 being not required to be removed, the channel length of the active channel sheet 110 may be maintained, and thus the current leakage may be effectively avoided.

As illustrated in FIGS. 1_a to 1_b, the substrate 105 is, for example, a portion of a silicon wafer. The substrate 105 has an upper surface 105u and a recess 105r recessed relative to the upper surface 105u. The substrate 105 includes at least one oxide definition (OD) region 1051. The OD region (or called “active region” or “active protrusion”) 1051 extends in X-axis. In the present embodiment, the doping layer 112 is further formed within the substrate 105. Furthermore, the doping layer 112 extends from an outer surface of the substrate 105 toward an inside of the substrate 105.

As illustrated in FIG. 1_b, the oxide layer 107 is, for example, a Shallow Trench Isolation (STI).

As illustrated in FIG. 1_a, the active channel sheet 110 may be formed of, for example, silicon. The active channel sheet 110 may be called “nanosheet”. The silicon epitaxy 108 is disposed within a wall of the recess 105r. The metal gate 115 is disposed on the active channel sheet 110. The inner spacer 120 is disposed a lateral surface of the metal gate 115. The isolation layer 125 is disposed over the silicon epitaxy 108.

As illustrated in FIG. 1_a, the first spacer 130 includes a first-sub spacer portion 131 and a second-sub spacer portion 132. The second-sub spacer portion 132 is disposed between the metal gate 115 and the first-sub spacer portion 131. In the present embodiment, the doping layer 112 is further formed within the first spacer 130. Furthermore, the doping layer 112 is further formed within the first-sub spacer portion 131 of the first spacer 130, and extends from a lateral surface of the first-sub spacer portion 131 toward an inside of the first spacer 130. In another embodiment, the doping layer 112 further extends to the second-sub spacer portion 132 of the first spacer 130.

As illustrated in FIGS. 1_a and 1_b, in an embodiment, the second spacer 165 includes the first-sub spacer portion 1651 and the second-sub spacer portion 1652. The first-sub spacer portion 131 may be formed of a material same as that of the first-sub spacer portion 1651, and the second-sub spacer portion 132 may be formed of a material same as that of the second-sub spacer portion 1652. The first-sub spacer portion 131 may be formed of a material different from that of the second-sub spacer portion 132, and the first-sub spacer portion 1651 may be formed of a material different from that of the second-sub spacer portion 1652. In terms of material, the first-sub spacer portion 131 may be formed of one of SiO, SiN, SiOC, SiON, SiOCN, etc., the second-sub spacer portion 132 may be formed of another of SiO, SiN, SiOC, SiON, SiOCN, etc. In an embodiment, the first-sub spacer portion 131 and the first-sub spacer portion 1651 may be formed in the same manufacture process (for example, deposition, etc.), and the second-sub spacer portion 132 and the second-sub spacer portion 1652 may be formed in the same manufacture process (for example, deposition, etc.). In another embodiment, the second spacers 165 may not cover recesses (or concaves) of the oxide layer 107 (in FIG. 1_b), and thus the doping layer 112 may be formed within sidewalls of the recesses of the oxide layer 107.

As illustrated in FIG. 1_a, the first dielectric layers 135 are formed on the active channel sheets 110, and the second dielectric layers 140 over the first dielectric layers 135 and the inner spacer 120 are formed by using, for example, deposition. In an embodiment, the first dielectric layers 135 is, for example, an interface layer IL, and the second dielectric layers 140 is, for example, High-k gate dielectric layer.

The High-k gate dielectric layer HK may be formed of a material including: (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9).

As illustrated in FIGS. 1_a and 1_b, the silicide layers 145 are formed over the exposed epitaxies 150. The epitaxy 150 may be formed over the isolation layer 125. The epitaxy 150 may be a source or a drain of a transistor. The CESL 155 is formed over the epitaxy 150 and the first-sub spacer portion 131 of the first spacer 130. The contact 160 is formed over the silicide layer 145, the CESL 155 and the epitaxy 150. The contacts 160 may be formed of a metal including the material the same as or similar to that of the metal gate 115. The ILD 170 is formed over the CESL 155 and has a plurality of holes exposing the silicide layers 145. The contacts 160 are formed within the holes of the ILD 170. The liner 175 is formed between the OD region 1051 and the oxide layer 107. The liner 175 covers a lateral surface of the oxide layer 107 to protect the oxide layer 107 from being damaged when the aforementioned doped film with high concentration is removed in the manufacturing processes of the semiconductor structure 100.

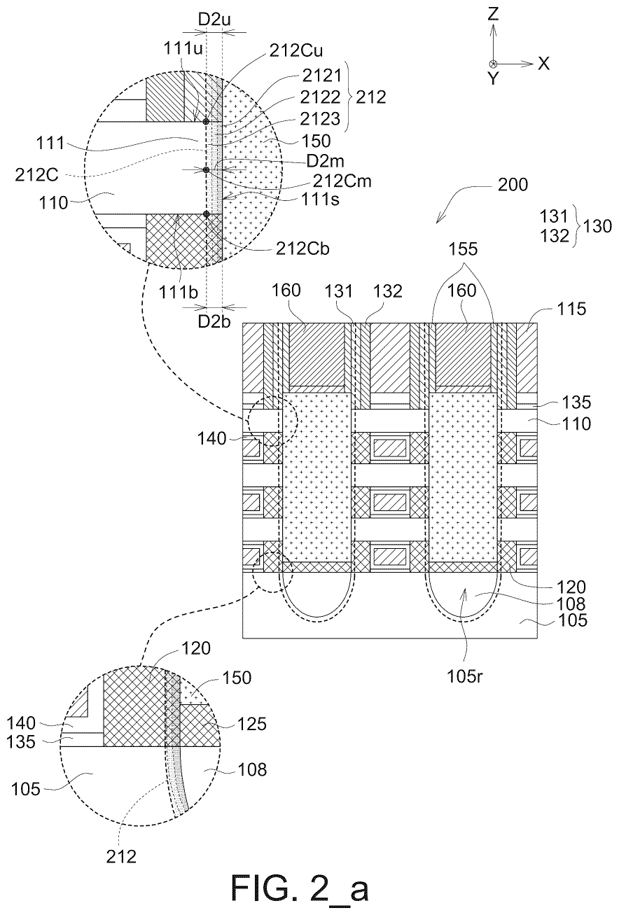

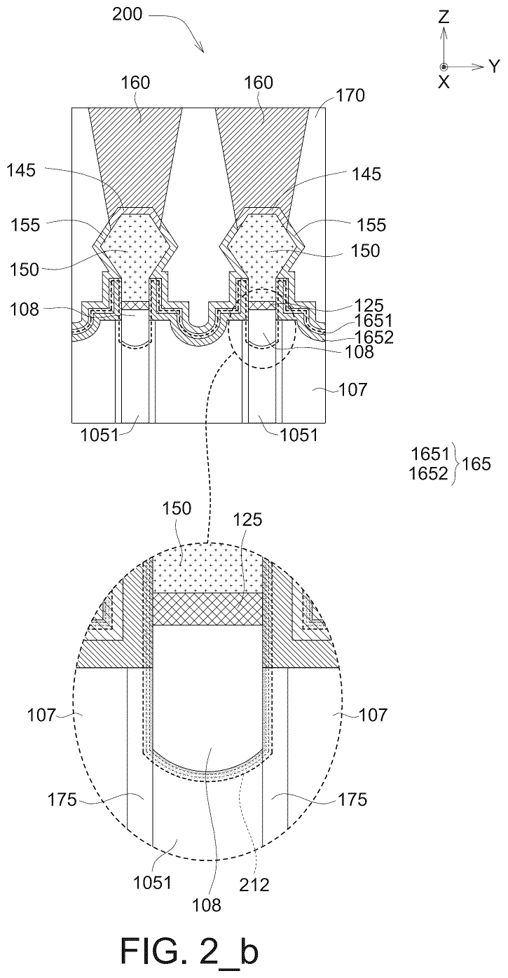

As illustrated in FIGS. 2_a to 2_b, FIG. 2_a illustrates a schematic diagram of a cross-sectional view of a local portion of a semiconductor structure 200 along a X-Z plane according to an embodiment of the present disclosure, and FIG. 2_b illustrates a schematic diagram of a cross-sectional view of the local portion of the semiconductor structure 200 along a Y-Z plane.

As illustrated in FIGS. 2_a and 2_b, the semiconductor structure 200 includes the substrate 105, the oxide layer 107, the silicon epitaxy 108, a plurality of the active channel sheets 110, at least one doping layer 212, a plurality of the metal gate 115, a plurality of the inner spacer 120, a plurality of the isolation layers 125, a plurality of the first spacer 130, a plurality of the first dielectric layer 135, a plurality of the second dielectric layer 140, the silicide layer 145, a plurality of the epitaxies 150, a plurality of the CESLs 155, a plurality of the contacts 160, a plurality of the second spacers 165, the interlayer dielectric 170 and a plurality of the liners 175.

As illustrated in FIGS. 2_a to 2_b, the active channel sheet 110 are stacked on the substrate 105 in a direction Z, wherein the active channel sheet 110 has the end portion 111 having the lateral surface 111s, the upper surface 111u and the lower surface 111b. The doping layer 212 is disposed within the end portion 111 of the active channel sheet 110. The doping layer 212 has a contour 212C having an upper point 212Cu adjacent to the upper surface 111u, a lower point 212Cb adjacent to the lower surface 111b and a middle point 212Cm between the upper point 212Cu and the lower point 212Cb, there is an upper distance D2u between the upper point 212Cu and the lateral surface 111s, there is a lower distance D2b between the lower point 212Cb and the lateral surface 111s, and there is a middle distance D2m between the middle point 212Cm and the lateral surface 111s. In the present embodiment, the upper distance D2u, the lower distance D2b and the middle distance D2m are approximately equal. The contour 212C is approximately parallel to the direction Z. Due to the design of the contour 212C, the gate may gain better control over the channel.

As illustrated in FIG. 2_a, in the present embodiment, the doping layer 212 is further formed within the first spacer 130. Furthermore, the doping layer 212 is further formed within the first-sub spacer portion 131 of the first spacer 130, and extends from a lateral surface of the first-sub spacer portion 131 toward an inside of the first spacer 130. In another embodiment, the doping layer 212 further extends to the second-sub spacer portion 132 of the first spacer 130.

As illustrated in FIG. 2_a, in the present embodiment, the doping layer 212 is further formed within the substrate 105. Furthermore, the doping layer 212 extends from an outer surface of the substrate 105 toward the inside of the substrate 105. In addition, the doping layer 212 is further formed within the inner spacer 120. Furthermore, doping layer 212 extends from a lateral surface of the inner spacer 120 toward an inside of the inner spacer 120.

As illustrated in FIG. 2_a, the doping layer 212 includes a plurality of doping regions (for example, 2121, 2122 and 2123) which have different concentrations. The doping regions 2121, 2122 and 2123 are distributed from outside to inside, wherein the doping concentration of the doping region 2121 is greater than that of the doping region 2122, and the doping concentration of the doping region 2122 is greater than that of the doping region 2123.

In an embodiment, the doping layer 212 includes boron or phosphorus. In an embodiment, the doping layer 212 may be formed by a doped film with high concentration, for example, a BSG film or a PSG film. The BSG film has a boron concentration of 2×10¹⁹cm⁻³¿5×10²¹cm⁻³, and the PSG film has a phosphorus concentration of 2×10¹⁹cm⁻³¿5×10²¹cm⁻³. The doping layer 212 may form a semiconductor layer with a component including silicon (for example, the substrate 105 and the active channel sheet 110). Due to the doping layer 212 being formed by the doped film, the end portion of the active channel sheet 110 is not required to be removed for filling epitaxial material. Due to the end portion of the active channel sheet 110 being not required to be removed, the channel length of the active channel sheet 110 may be maintained, and thus the current leakage may be effectively avoided. In another embodiment, the second spacers 165 may not cover recesses of the oxide layer 107, and thus the doping layer 212 may be formed within sidewalls of the recesses of the oxide layer 107.

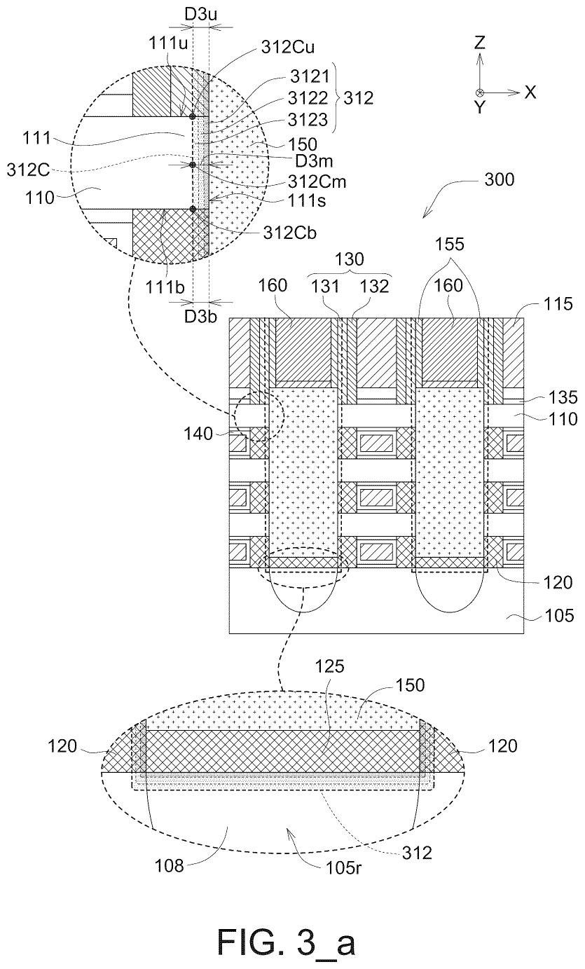

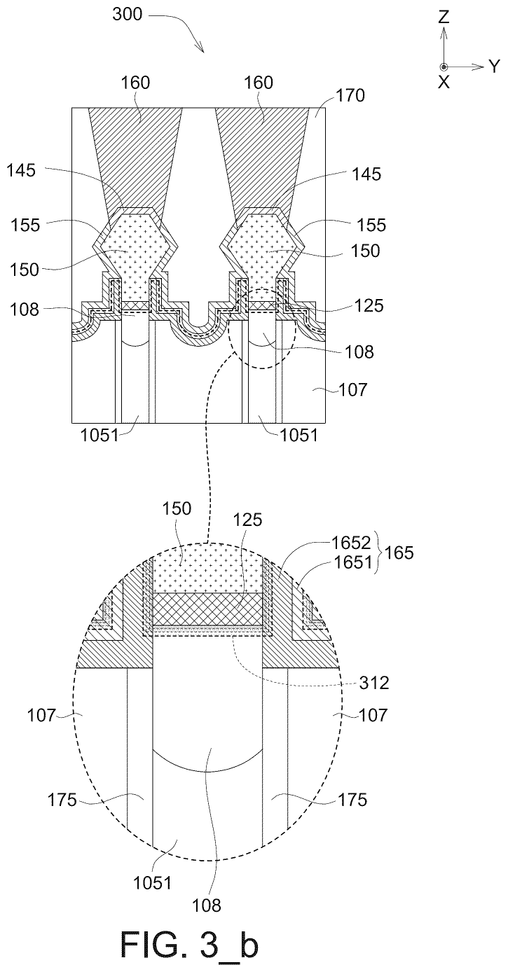

As illustrated in FIGS. 3_a to 3_b, FIG. 3_a illustrates a schematic diagram of a cross-sectional view of a local portion of a semiconductor structure 300 along a X-Z plane according to an embodiment of the present disclosure, and FIG. 3_b illustrates a schematic diagram of a cross-sectional view of the local portion of the semiconductor structure 300 along a Y-Z plane.

As illustrated in FIGS. 3_a and 3_b, the semiconductor structure 300 includes the substrate 105, the oxide layer 107, the silicon epitaxy 108, a plurality of the active channel sheets 110, at least one doping layer 312, a plurality of the metal gates 115, a plurality of the inner spacers 120, a plurality of the isolation layers 125, a plurality of the first spacers 130, a plurality of the first dielectric layers 135, a plurality of the second dielectric layers 140, a plurality of the silicide layers 145, a plurality of the epitaxies 150, a plurality of the CESLs 155, a plurality of the contacts 160, a plurality of the second spacers 165, the interlayer dielectric 170 and a plurality of the liners 175.

As illustrated in FIGS. 3_a to 3_b, the active channel sheets 110 are stacked on the substrate 105 in a direction Z, wherein the active channel sheet 110 has the end portion 111 having the lateral surface 111s, the upper surface 111u and the lower surface 111b. The doping layer 312 is disposed within the end portion 111 of the active channel sheet 110. The doping layer 312 has a contour 312C having the upper point 312Cu adjacent to the upper surface 111u, a lower point 312Cb adjacent to the lower surface 111b and a middle point 312Cm between the upper point 312Cu and the lower point 312Cb, there is an upper distance D3u between the upper point 312Cu and the lateral surface 111s, there is a lower distance D3b between the lower point 312Cb and the lateral surface 111s, and there is a middle distance D3m between the middle point 312Cm and the lateral surface 111s. In the present embodiment, the upper distance D3u, the lower distance D3b and the middle distance D3m are approximately equal. The contour 312C is approximately parallel to the direction Z. Due to the design of the contour 312C, the gate may gain better control over the channel.

As illustrated in FIG. 3_a, in the present embodiment, the doping layer 312 is further formed within the first spacer 130. Furthermore, the doping layer 312 is further formed within the first-sub spacer portion 131 of the first spacer 130, and extends from a lateral surface of the first-sub spacer portion 131 toward an inside of the first spacer 130. In another embodiment, the doping layer 312 further extends to the second-sub spacer portion 132 of the first spacer 130.

As illustrated in FIG. 3_a, in the present embodiment, the doping layer 312 is further formed within the silicon epitaxy 108. Furthermore, the doping layer 312 extends from an outer surface of the silicon epitaxy 108 toward the inside of the silicon epitaxy 108. In addition, the doping layer 312 is further formed within the inner spacer 120. Furthermore, doping layer 312 extends from a lateral surface of the inner spacer 120 toward an inside of the inner spacer 120.

As illustrated in FIG. 3_a, the doping layer 312 includes a plurality of doping regions (for example, 3121, 3122 and 3123) which have different concentrations. The doping regions 3121, 3122 and 3123 are distributed from outside to inside, wherein the doping concentration of the doping region 3121 is greater than that of the doping region 3122, and the doping concentration of the doping region 3122 is greater than that of the doping region 3123.

In an embodiment, the doping layer 312 includes boron or phosphorus. In an embodiment, the doping layer 312 may be formed by a doped film with high concentration, for example, a BSG film or a PSG film. The BSG film has a boron concentration of 2×10¹⁹cm⁻³¿5×10²¹cm⁻³, and the PSG film has a phosphorus concentration of 2×10¹⁹cm⁻³¿5×10²¹cm⁻³. The doping layer 312 may form a semiconductor layer with a component including silicon (for example, the silicon epitaxy 108 and the active channel sheet 110). Due to the doping layer 312 being formed by the doped film, the end portion of the active channel sheet 110 is not required to be removed for filling epitaxial material. Due to the end portion of the active channel sheet 110 being not required to be removed, the channel length of the active channel sheet 110 may be maintained, and thus the current leakage may be effectively avoided. In another embodiment, the second spacers 165 may not cover recesses of the oxide layer 107, and the doping layer 312 may be formed within sidewalls of the recesses of the oxide layer 107.

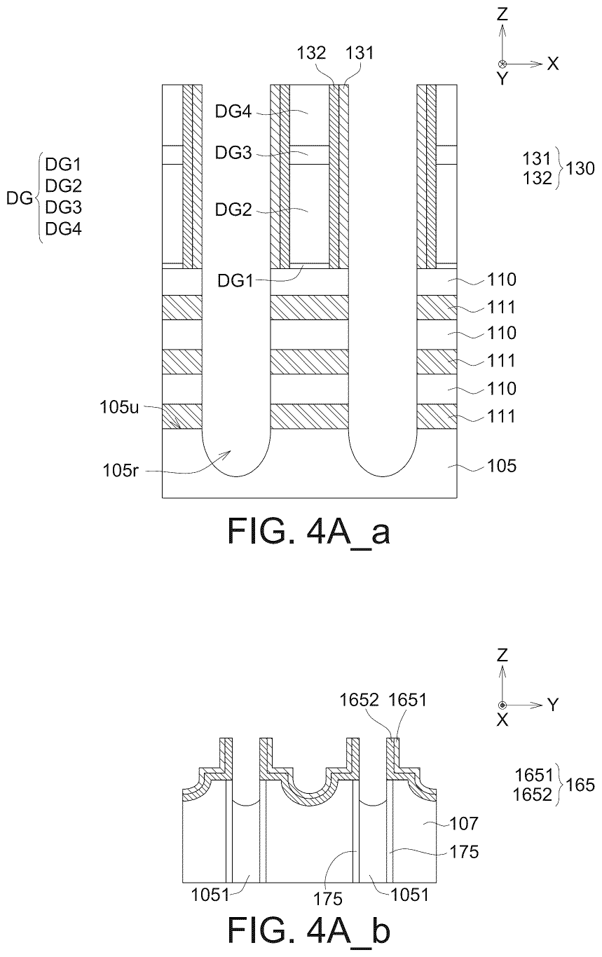

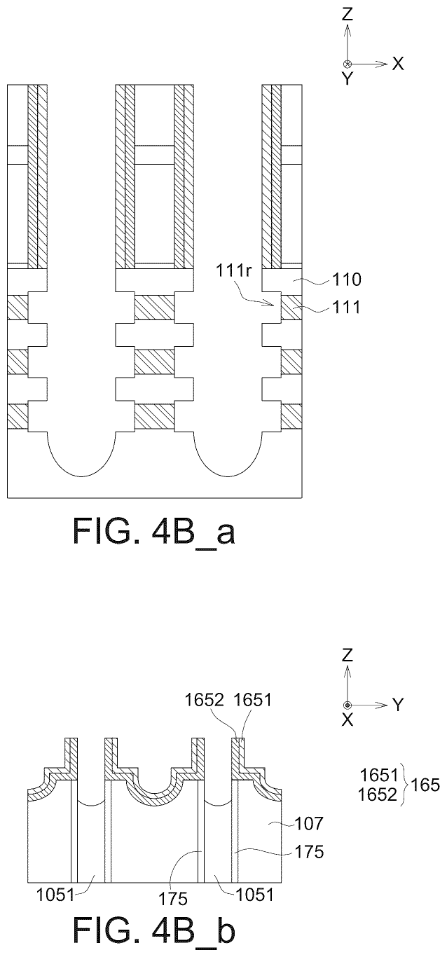

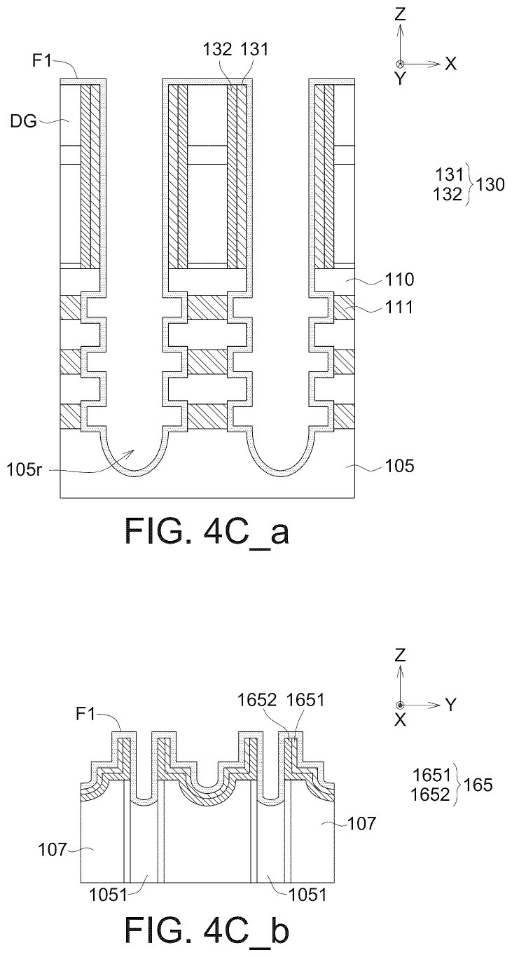

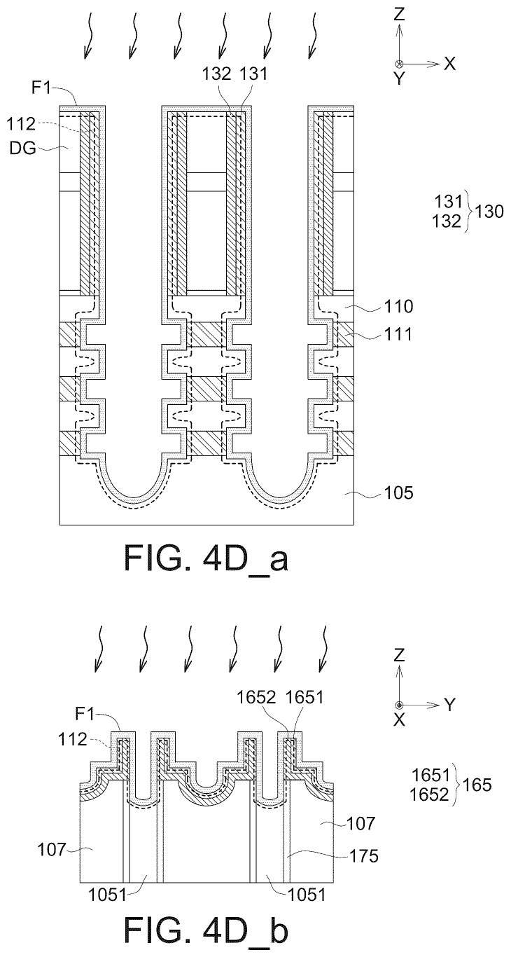

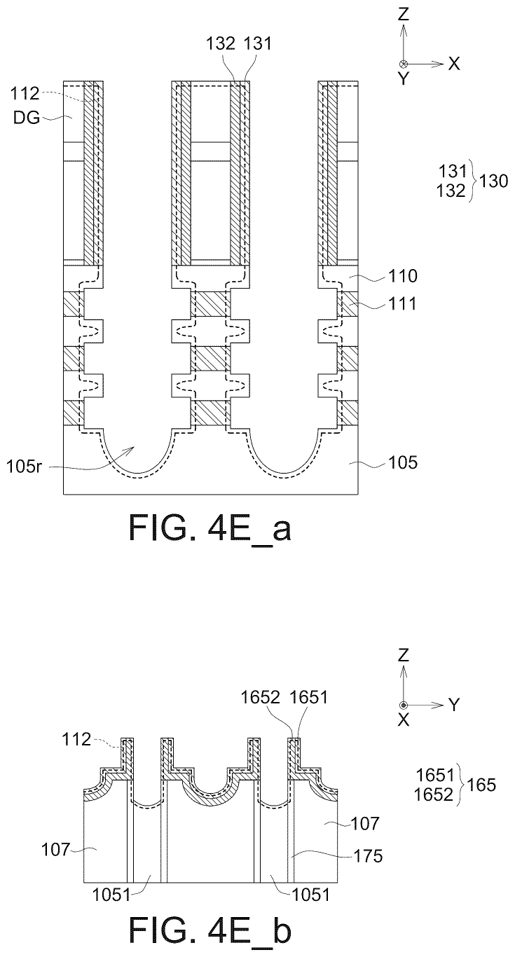

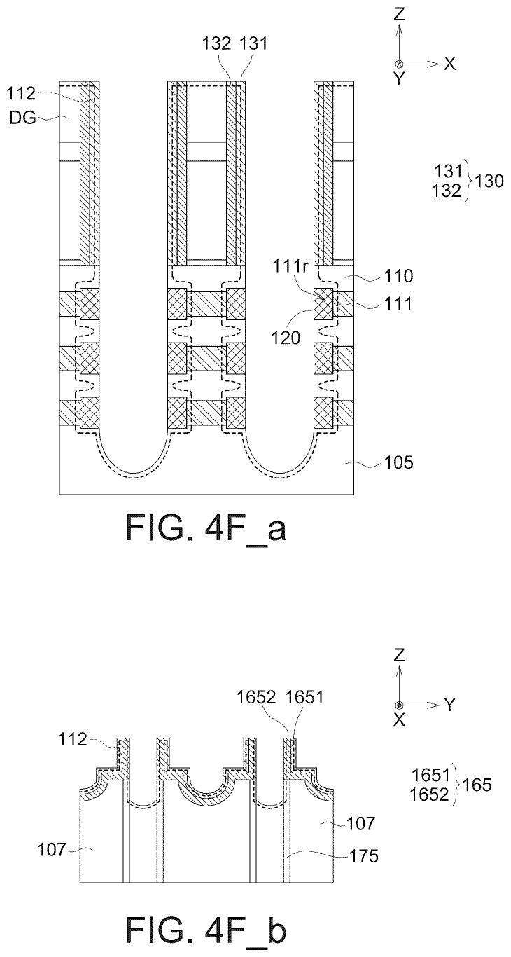

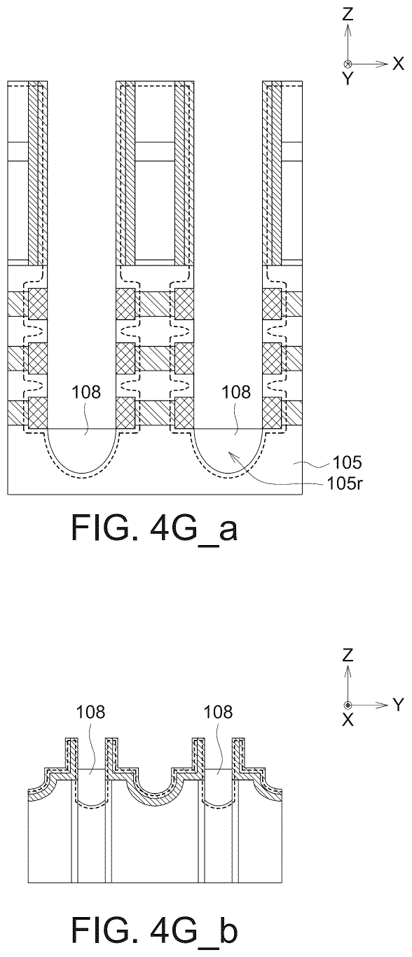

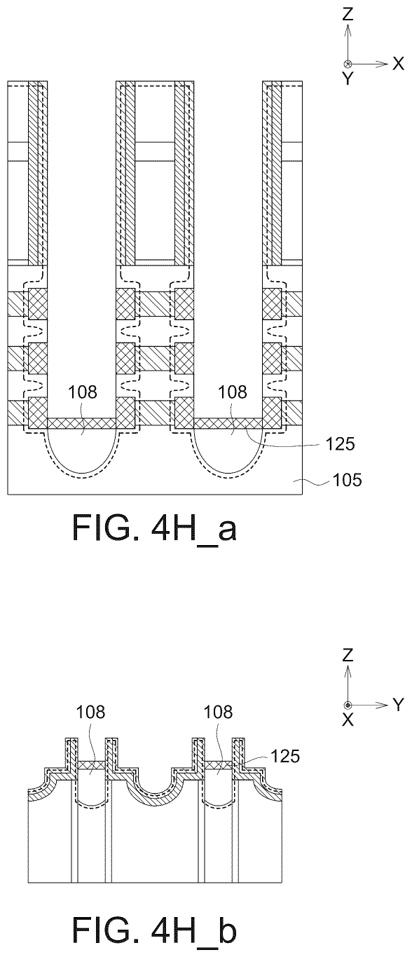

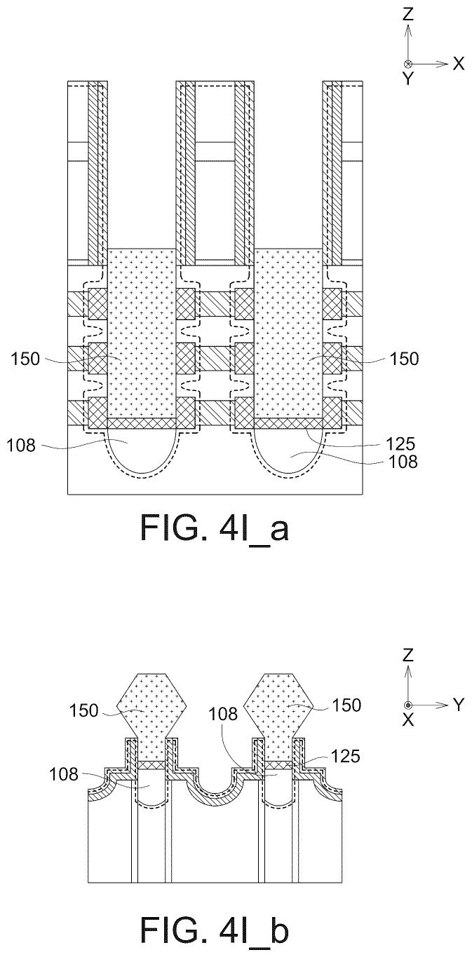

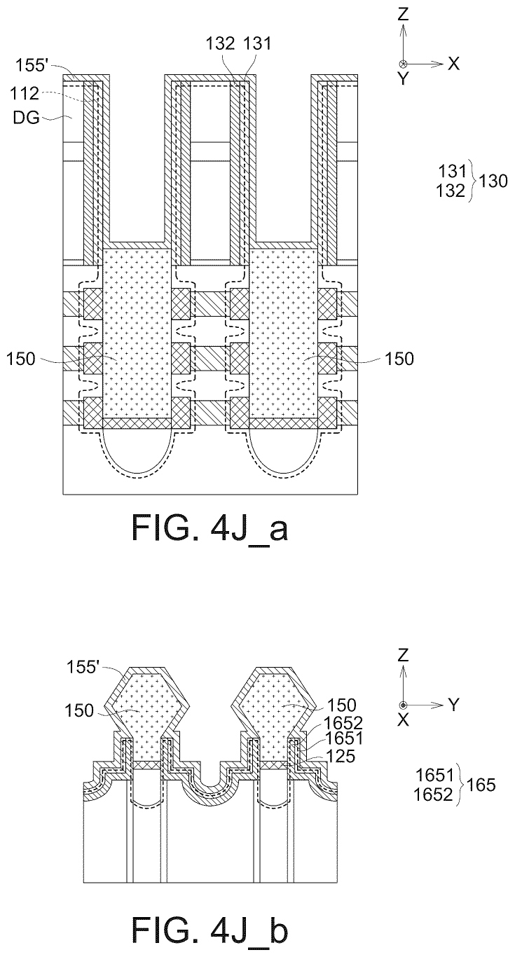

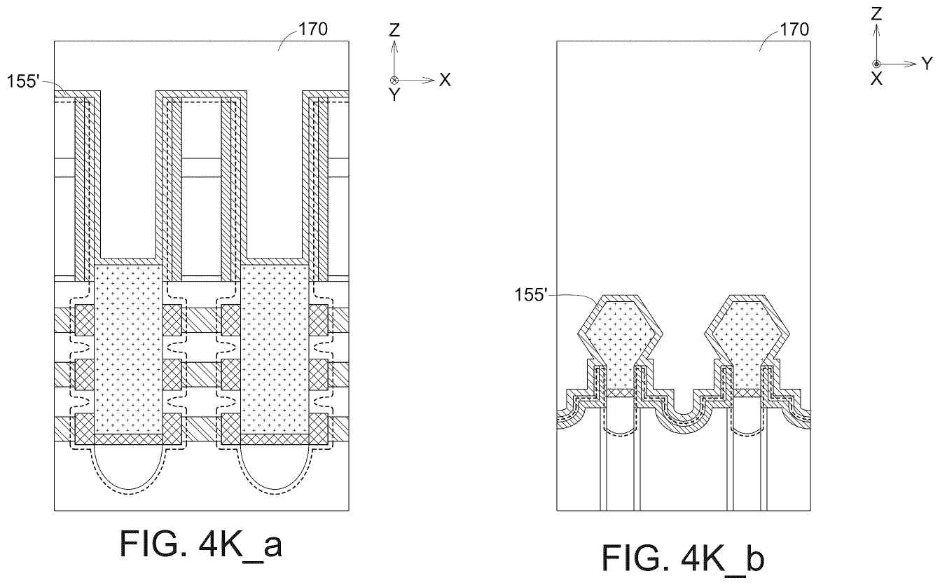

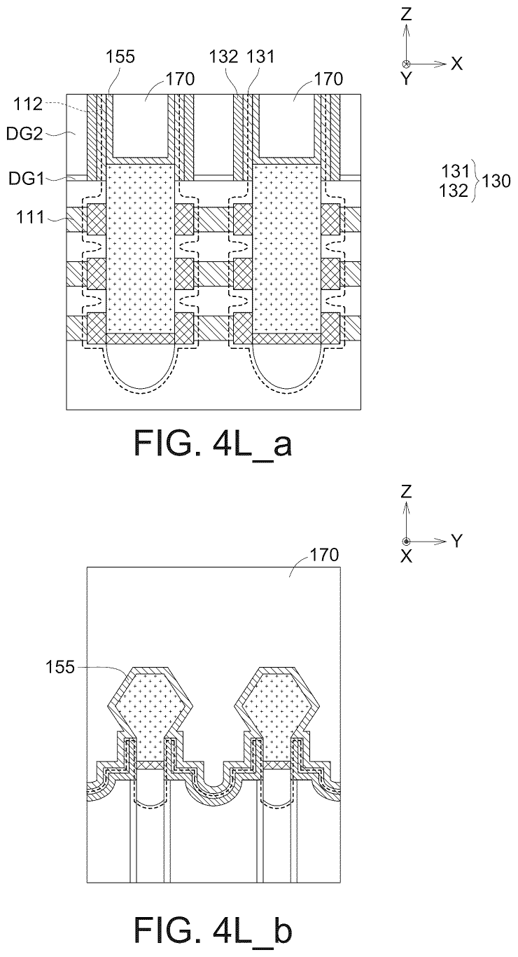

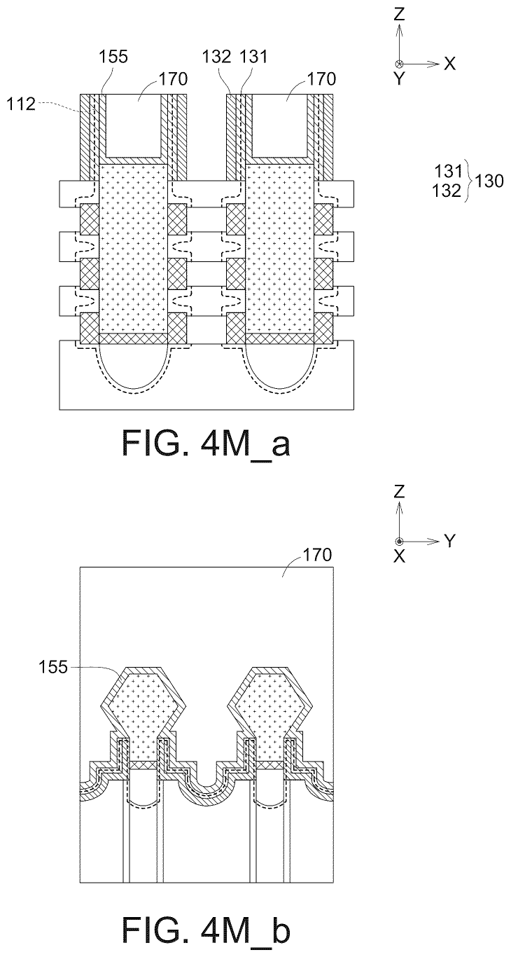

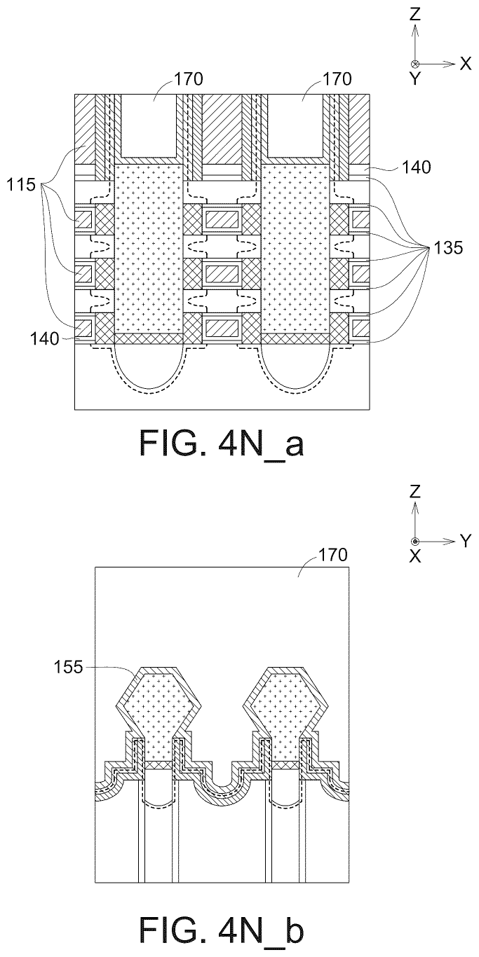

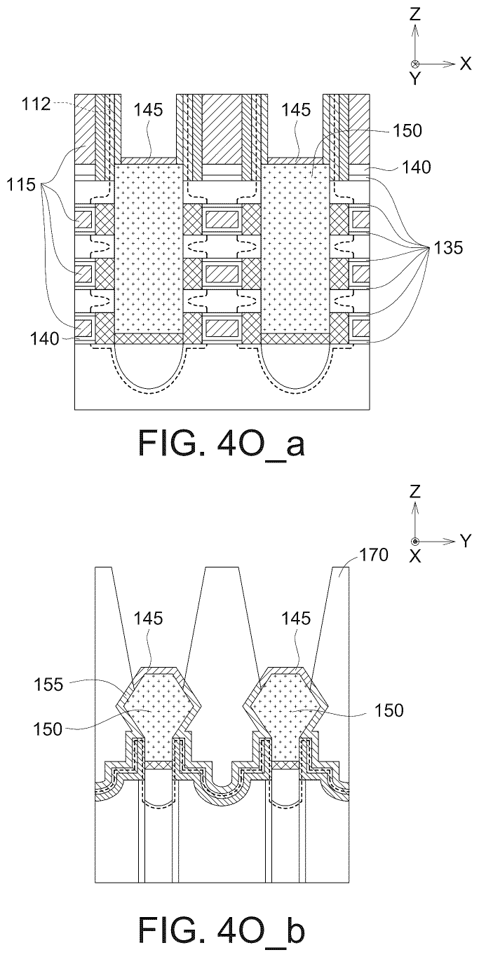

FIGS. 4A_a to 4O_b illustrate schematic diagrams of manufacturing processes of the semiconductor structure 100 in FIGS. 1_a to 1_b.

As illustrated in FIGS. 4A_a to 4A_b, a plurality of the active channel sheet 110 and a plurality of silicon germanium (SiGe) layers 111 are stacked on the substrate 105. Each active channel sheet 110 is formed of, for example, silicon. One of the active channel sheets 110 may be formed between adjacent two of the SiGe layers 111. In addition, the substrate 105 has the upper surface 105u and the recess 105r recessed relative to the upper surface 105u.

The dummy gate structures DG are formed on the active channel sheets 110 by depositing, and then the first spacer 130 is formed on adjacent two sides of the corresponding dummy gate structure DG. The first spacer 130 includes the first-sub spacer portion 131 and the second-sub spacer portion 132, wherein the second-sub spacer portion 132 is disposed between the dummy gate structures DG and the first-sub spacer portion 131. In an embodiment, the first-sub spacer portion 131 may be formed of a material different from that of the second-sub spacer portion 132. The first-sub spacer portion 131 may be formed of one of SiO, SiN, SiOC, SiON, SiOCN, etc., the second-sub spacer portion 132 may be formed of another of SiO, SiN, SiOC, SiON, SiOCN, etc.

The dummy gate structure DG includes a dummy dielectric layer DG1, a dummy gate layer DG2, a mask layer DG3 and an oxide layer DG4. The dummy dielectric layer DG1 is formed on the fin structures. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

In FIG. 4A_b, the substrate 105 includes a plurality of the OD regions 1051 extending in X-axis. The oxide layer 107 on the adjacent two sides of the OD regions 1051 is formed by using, for example, deposition. The liner 175 is formed between the OD region 1051 and the oxide layer 107. The liner 175 covers a lateral surface of the oxide layer 107 to protect the oxide layer 107. The oxide layer 107 is, for example, a STI. The second spacers 165 are formed over the oxide layer 107. The second spacer 165 includes the first-sub spacer portion 1651 and the second-sub spacer portion 1652. The first-sub spacer portion 1651 may be formed of a material different from that of the second-sub spacer portion 1652. In terms of material, the first-sub spacer portion 1651 may be formed of one of SiO, SiN, SiOC, SiON, SiOCN, etc., and the second-sub spacer portion 1652 may be formed of another of SiO, SiN, SiOC, SiON, SiOCN, etc. In another embodiment, the second spacers 165 may not cover recesses of the oxide layer 107, and thus the subsequent doped film F1 (as illustrated in FIG. 4C_b) may be formed on sidewalls of the recesses of the oxide layer 107, and the doping layer 112 (as illustrated in FIG. 4D_b) may be formed within sidewalls of the recesses of the oxide layer 107.

In an embodiment, the second-sub spacer portion 132 and the second-sub spacer portion 1652 may be formed in the same deposition process, and the first-sub spacer portion 131 and the first-sub spacer portion 1651 may be formed in the same deposition process. The first-sub spacer portion 131 may be formed of a material same as that of the first-sub spacer portion 1651, and the second-sub spacer portion 132 may be formed of a material same as that of the second-sub spacer portion 1652. In an embodiment, the first-sub spacer portion 131 and the first-sub spacer portion 1651 may be formed in the same manufacture process (for example, deposition, etc.), and the second-sub spacer portion 132 and the second-sub spacer portion 1652 may be formed in the same manufacture process (for example, deposition, etc.).

As illustrated in FIGS. 4B_a to 4B_b, a plurality of the recesses 111r in the SiGe layers 111 are formed by using, for example, etching. The recess 111r is recessed relative to the lateral surface 111s of the active channel sheet 110.

As illustrated in FIGS. 4C_a to 4C_b, a doped film F1 with high concentration, for example, a BSG film or a PSG film is formed by, for example, deposition. In an embodiment, the doped film F1 is a solid-phase film (for example, dopant glass film). The BSG film has a boron concentration of 2×10¹⁹cm⁻³¿5×10²¹cm⁻³, and the PSG film has a phosphorus concentration of 2×10¹⁹cm⁻³¿5×10²¹cm⁻³. The doped film F1 covers outer surfaces of the substrate 105, the wall of the recess 105r, the active channel sheets 110, the SiGe layers 111, the first spacers 130, the dummy gate structures DG, the second spacers 165. The doped film F1 has a thickness of 1 nanometers (nm). Although not illustrated, a cap film may be formed over the doped film F1, and the cap film has a thickness of 2 nm.

As illustrated in FIGS. 4D_a to 4D_b, the structure in FIGS. 4D_a and 4D_b may be heated to make the dopant thermally driven into the layers (for example, the substrate 105, the wall of the recess 105r, the active channel sheets 110, the SiGe layers 111, the first spacers 130, the dummy gate structures DG, the second spacers 165) which are covered by the doped film F1 to form the doping layer 112 in these layers. The heating process includes, for example, annealing (for example, flash annealing), RTA (rapid thermal annealing), etc.

As illustrated in FIGS. 4E_a to 4E_b, the doped film F1 in FIGS. 4D_a to 4D_b is removed by, for example, etching, etc. to expose these layers (for example, the substrate 105, the OD regions 1051, the wall of the recess 105r, the active channel sheets 110, the recesses 111r, the first spacers 130, the dummy gate structures DG, the second spacers 165) which by the doped film F1 in FIGS. 4D_a and 4D_b. In addition, due to the oxide layer 107 being covered by the liner 175 and the second spacers 165, the oxide layer 107 and the second spacers 165 may be prevented from being damaged when the doped film F1 (also includes oxide material) is removed.

As illustrated in FIGS. 4F_a to 4F_b, the inner spacers 120 are formed within the recesses 111r by deposition, etching, etc. Due to the inner spacers 120 being formed after the removal of the doped film F1, the doping layer 112 is not formed within the inner spacers 120.

As illustrated in FIGS. 4G_a to 4G_b, the epitaxial silicon 108 may be formed within the recess 105r by, for example, epitaxy process, etc.

As illustrated in FIGS. 4H_a to 4H_b, the isolation layer 125 over the epitaxial silicon 108 by using, for example, deposition, exposure, etching, development, etc.

As illustrated in FIGS. 4I_a to 4I_b, the epitaxies 150 may be formed over the isolation layer 125. The isolation layer 125 between the epitaxy 150 and the epitaxial silicon 108 (or the substrate 105) may increase the isolation between the adjacent two of the epitaxies 150. Due to the end portion of the active channel sheet is not required to be removed, the robust and uniform source/drain (epitaxies 150) dopant coverage across sheet width and across sheets may be obtained.

As illustrated in FIGS. 4J_a to 4J_b, a CESL material 155′ over the first spacers 130, the epitaxies 150, the second spacers 165 and upper surfaces of the dummy gate structures DG are formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like.

As illustrated in FIGS. 4K_a to 4K_b, the ILD 170 covering the CESL material 155′ is formed by using, for example, deposition, such as CVD, PECVD, or flowable chemical vapor deposition (FCVD), or the like. The ILD 170 may be formed of a dielectric including, for example, PSG, BSG, boron-doped phospho-silicate glass (BPSG), undoped silicate glass (USG), or the like. Other insulation materials formed by any acceptable process may be used.

As illustrated in FIGS. 4L_a to 4L_b, the ILD 170, the CESL material 155′ and the dummy gate structures DG may be planarized by using, for example, Chemical-Mechanical Polishing (CMP). After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layer DG, the first-sub spacer portion 131, the second-sub spacer portion 132 and the ILD 170 may form, for example, a planarized surface.

As illustrated in FIGS. 4M_a to 4M_b, the SiGe layers 111 and the dummy dielectric layer DG1 and the dummy gate layer DG2 of the dummy gate structure DG in FIG. 4L_a may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the SiGe layers 111 can also be removed by using, for example, etching. After the dummy gate structures DG and the SiGe layers 111 are removed, the active channel sheets 110 are exposed.

As illustrated in FIGS. 4N_a to 4N_b, the first dielectric layers 135 are formed on the active channel sheets 110 by using, for example, deposition. Then, the second dielectric layer 140 over the inner spacer 120 and the first dielectric layers 135 are formed by using, for example, deposition. Then, the metal gate 115 over the second dielectric layer 140 and the first spacer 130 is formed by a process such as ALD, CVD, PVD, remote plasma CVD (RPCVD), plasma enhanced CVD (PECVD), metal-organic CVD (MOCVD), sputtering, electroplating, other suitable processes, or the like.

As illustrated in FIGS. 4O_a to 4O_b, a portion of the ILD 170 and a bottom portion of the CESL 155 in FIG. 4N_a are removed to expose the epitaxies 150 by using, for example, deposition, exposure, etching, development, etc. Then, the silicide layers 145 over the exposed epitaxies 150 are formed by using, for example, deposition.

Then, the contacts 160 in FIGS. 1_a and 1_a are formed over the CESL 155 and the epitaxies 150 in FIGS. 4O_a to 4O_b to form at least one semiconductor structure 100 as illustrated in FIGS. 1_a and 1_b. The contacts 160 may be formed of a metal including the material the same as or similar to that of the metal gate 115.

In another embodiment, the doping layer 112 in FIGS. 1_a and 1_b may be formed by using, for example, a plasma implant (for example, isotropic plasma). Furthermore, after step of FIGS. 4B_a and 4B_b, the doping layer 112 (as illustrated in FIGS. 4D_a and 4D_b) may be formed by the plasma implant. In this example, the formation of the doped film F1 (as illustrated in FIGS. 4C_a and 4C_b) and the heating process (as illustrated in FIGS. 4D_a and 4D_b) may be omitted. In this example, other manufacturing steps may be the same as or similar to the corresponding manufacturing steps of the semiconductor structure 100, and they will not be repeated here.

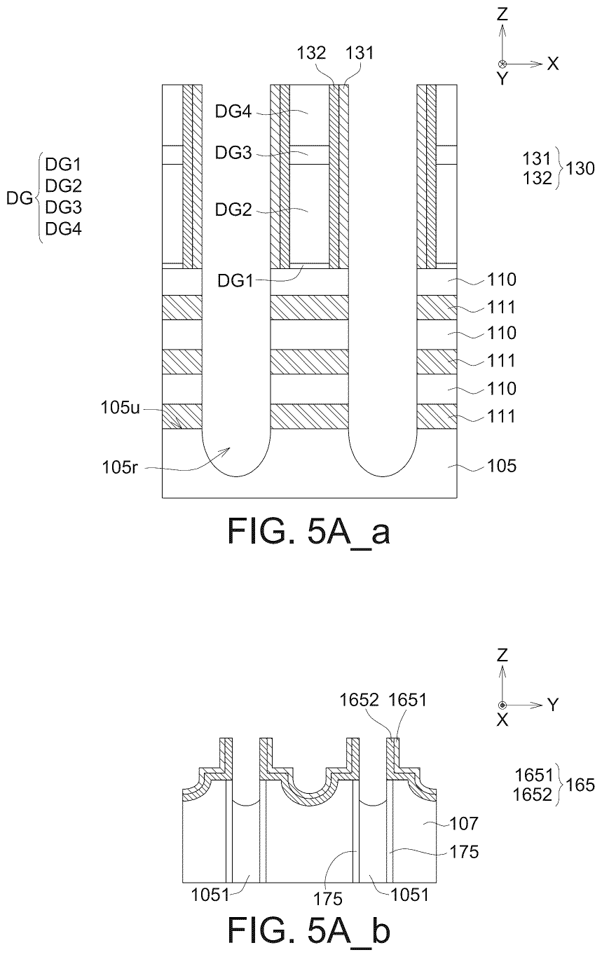

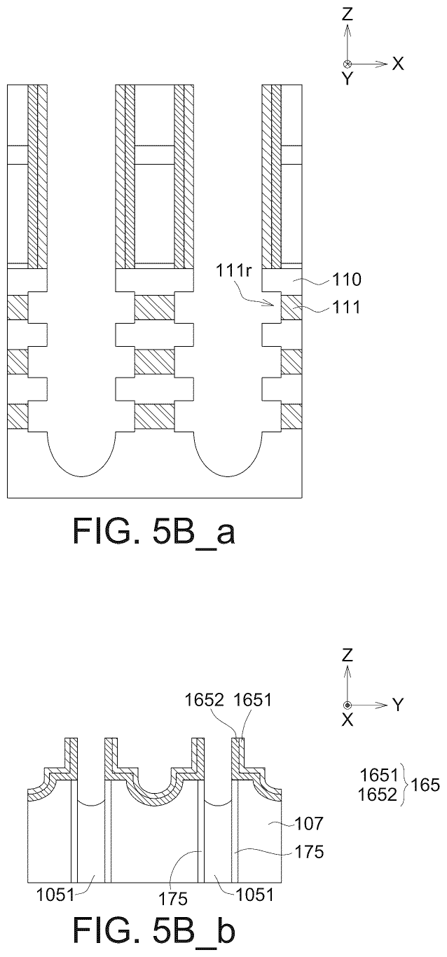

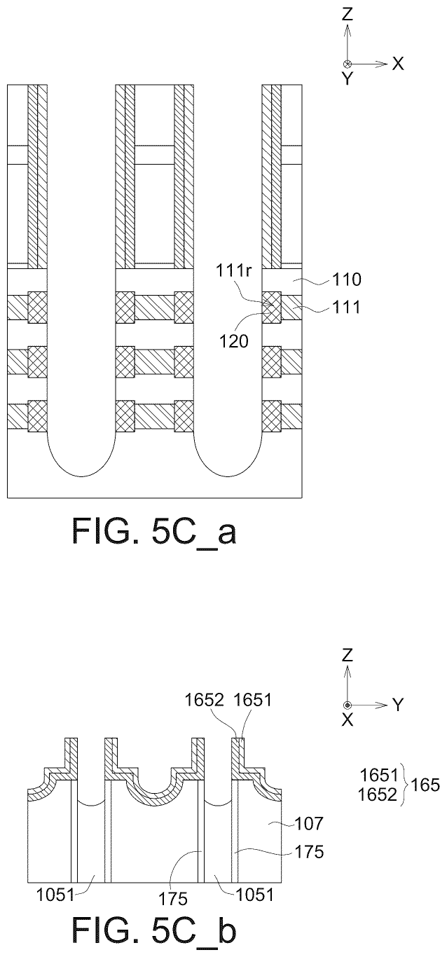

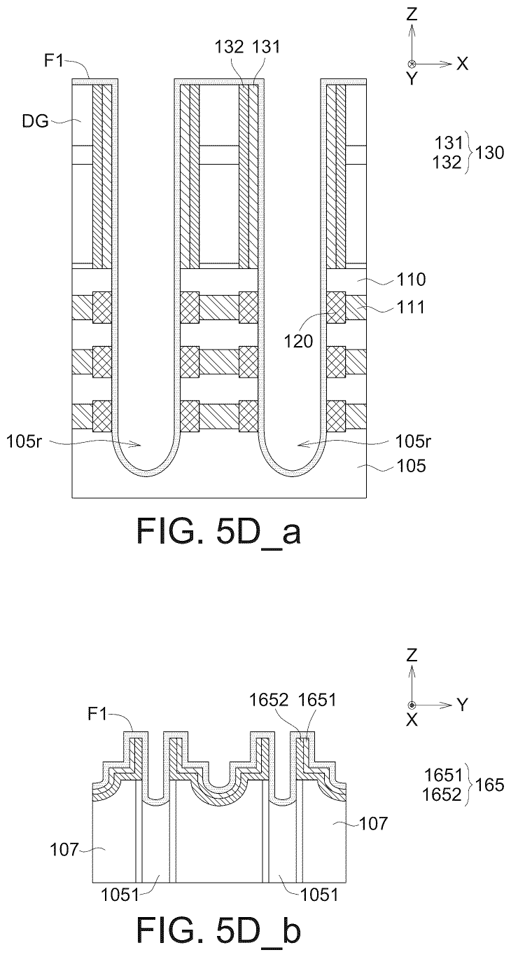

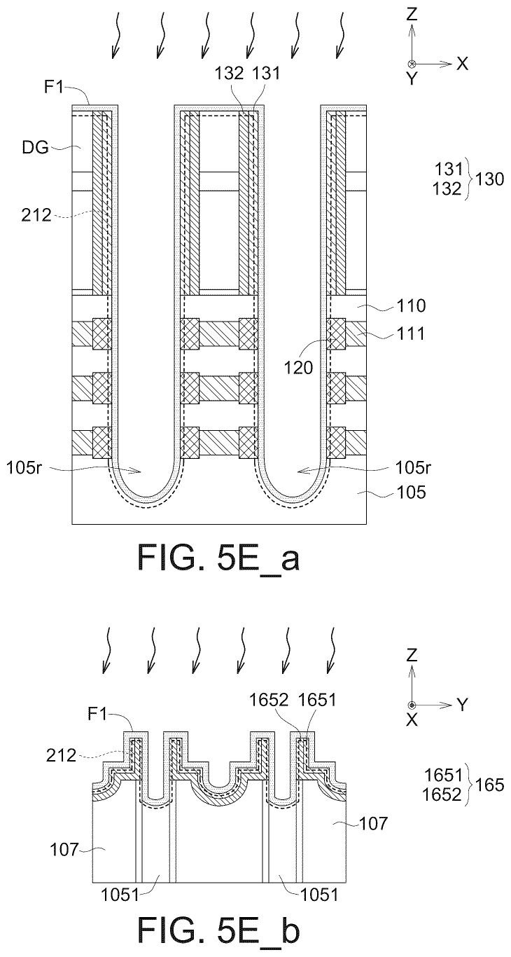

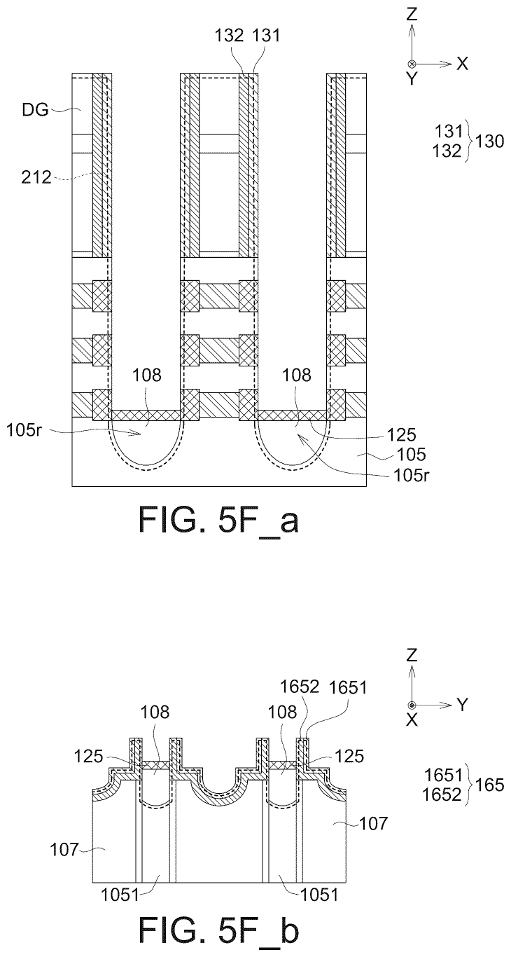

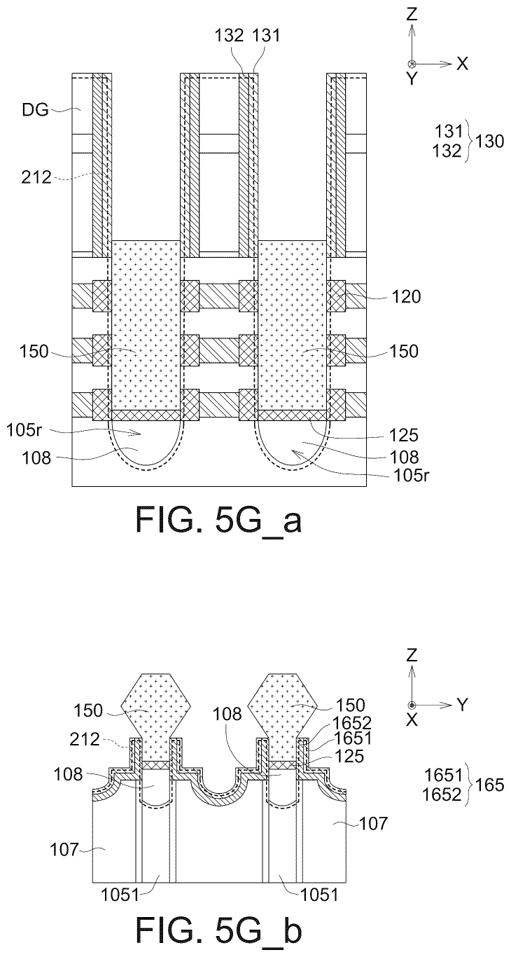

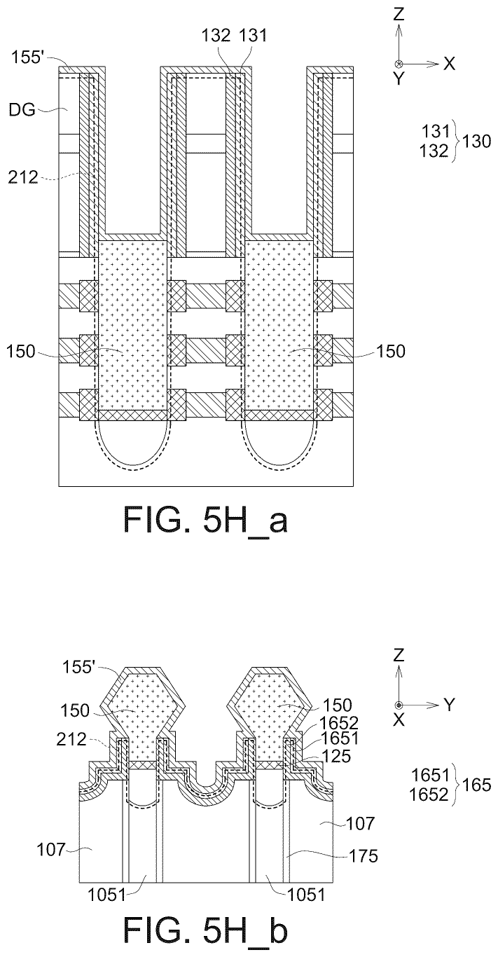

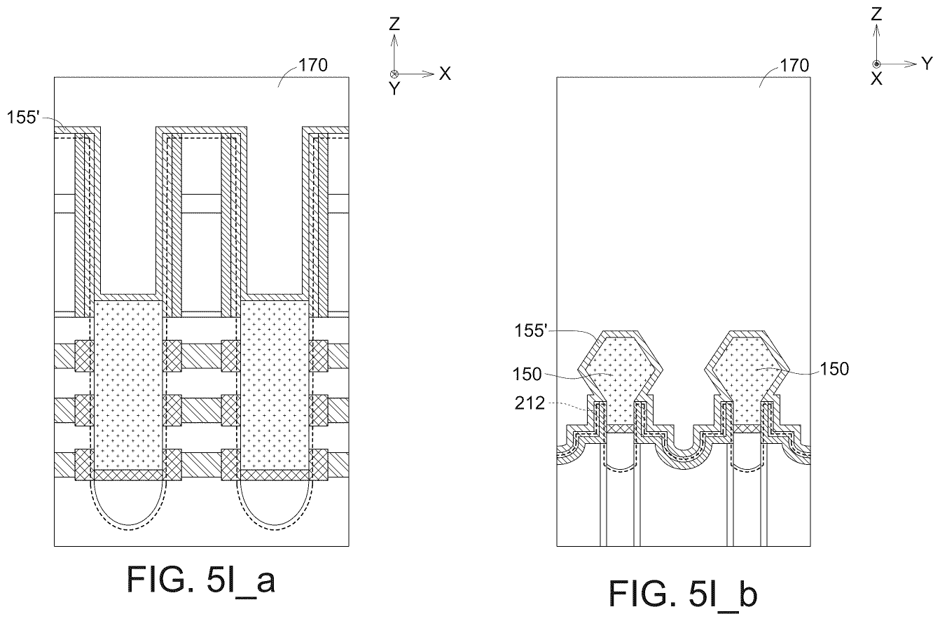

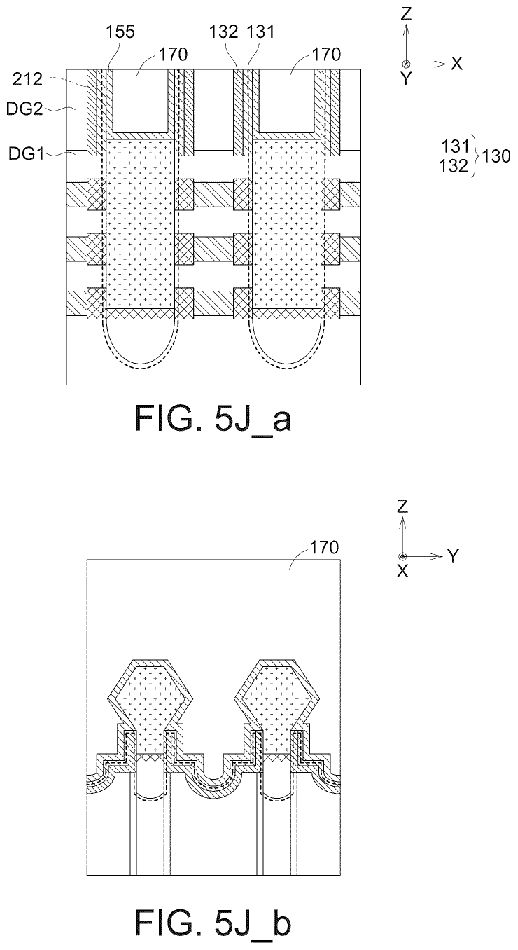

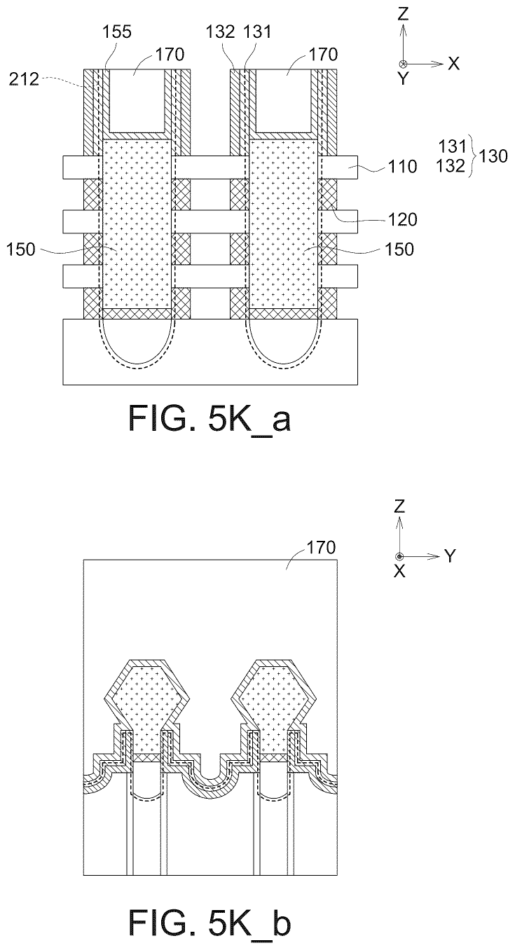

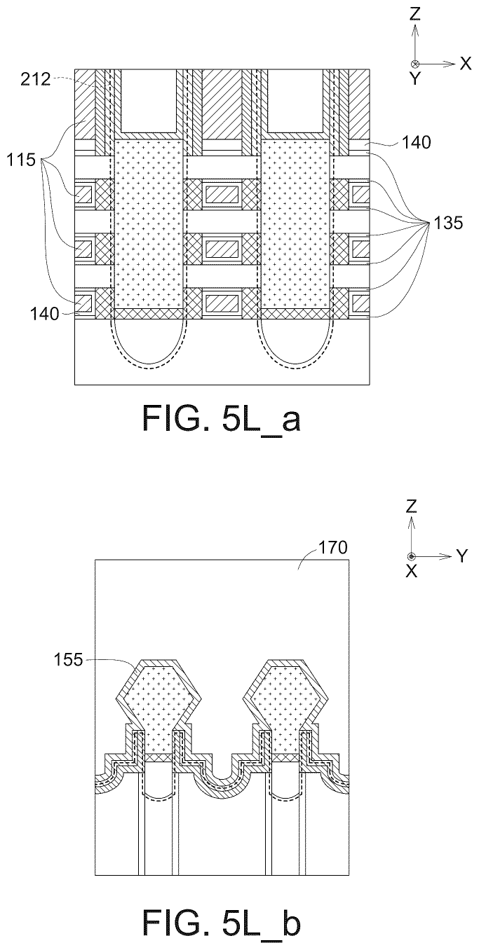

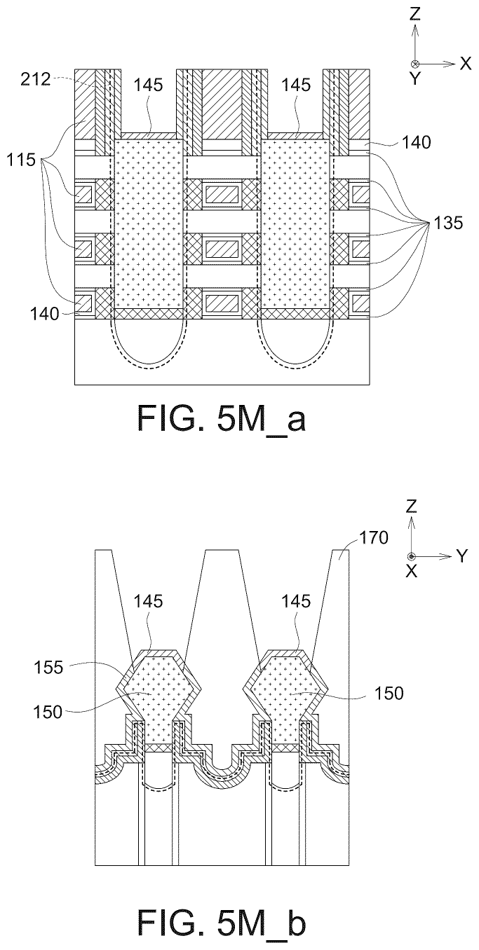

FIGS. 5A_a to 5M_b illustrate schematic diagrams of manufacturing processes of the semiconductor structure 200 in FIG. 2_a to 2_b.

As illustrated in FIGS. 5A_a to 5A_b, a plurality of the active channel sheet 110 and a plurality of SiGe layers 111 are stacked on the substrate 105. Each active channel sheet 110 is formed of, for example, silicon. One of the active channel sheets 110 may be formed between adjacent two of the SiGe layers 111. In addition, the substrate 105 has the upper surface 105u and the recess 105r recessed relative to the upper surface 105u. In another embodiment, the second spacers 165 may not cover the recesses of the oxide layer 107, and thus the subsequent doped film F1 (as illustrated in FIG. 5D_b) may be formed on the sidewalls of the recesses of the oxide layer 107, and the doping layer 212 (as illustrated in FIG. 5E_b) may be formed within the sidewalls of the recesses of the oxide layer 107.

The dummy gate structures DG are formed on the active channel sheets 110 by depositing, and then the first spacer 130 is formed on adjacent two sides of the corresponding dummy gate structure DG. The first spacer 130 includes the first-sub spacer portion 131 and the second-sub spacer portion 132, wherein the second-sub spacer portion 132 is disposed between the dummy gate structures DG and the first-sub spacer portion 131. In an embodiment, the first-sub spacer portion 131 may be formed of a material different from that of the second-sub spacer portion 132. The first-sub spacer portion 131 may be formed of one of SiO, SiN, SiOC, SiON, SiOCN, etc., the second-sub spacer portion 132 may be formed of another of SiO, SiN, SiOC, SiON, SiOCN, etc.

The dummy gate structure DG includes a dummy dielectric layer DG1, a dummy gate layer DG2, a mask layer DG3 and an oxide layer DG4. The dummy dielectric layer DG1 is formed on the fin structures. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

In FIG. 5A_b, the substrate 105 includes a plurality of the OD regions 1051 extending in X-axis. The oxide layer 107 on the adjacent two sides of the OD regions 1051 is formed by using, for example, deposition. The liner 175 is formed between the OD region 1051 and the interlayer dielectric 170. The liner 175 covers a lateral surface of the interlayer dielectric 170 to protect the interlayer dielectric 170. The oxide layer 107 is, for example, a STI. The second spacers 165 are formed over the oxide layer 107. The second spacer 165 includes the first-sub spacer portion 1651 and the second-sub spacer portion 1652. The first-sub spacer portion 1651 may be formed of a material different from that of the second-sub spacer portion 1652. In terms of material, the first-sub spacer portion 1651 may be formed of one of SiO, SiN, SiOC, SiON, SiOCN, etc., and the second-sub spacer portion 1652 may be formed of another of SiO, SiN, SiOC, SiON, SiOCN, etc.

In an embodiment, the second-sub spacer portion 132 and the second-sub spacer portion 1652 may be formed in the same deposition process, and the first-sub spacer portion 131 and the first-sub spacer portion 1651 may be formed in the same deposition process. The first-sub spacer portion 131 may be formed of a material same as that of the first-sub spacer portion 1651, and the second-sub spacer portion 132 may be formed a material same as that of the second-sub spacer portion 1652. In an embodiment, the first-sub spacer portion 131 and the first-sub spacer portion 1651 may be formed in the same manufacture process (for example, deposition, etc.), and the second-sub spacer portion 132 and the second-sub spacer portion 1652 may be formed in the same manufacture process (for example, deposition, etc.).

As illustrated in FIGS. 5B_a to 5B_b, a plurality of the recesses 111r in the SiGe layers 111 are formed by using, for example, etching. The recess 111r is recessed relative to the lateral surface 111s of the active channel sheet 110.

As illustrated in FIGS. 5C_a to 5C_b, the inner spacers 120 are formed within the recesses 111r by deposition, etching, etc.

As illustrated in FIGS. 5D_a to 5D_b, the doped film F1 with high concentration, for example, the BSG film or the PSG film is formed by, for example, deposition. In an embodiment, the doped film F1 is a solid-solid-phase film (for example, dopant glass film). The BSG film has the boron concentration of 2×10¹⁹cm⁻³¿5×10²¹cm⁻³, and the PSG film has the phosphorus concentration of 2×10¹⁹cm⁻³¿5×10²¹cm⁻³. The doped film F1 cover outer surfaces of the substrate 105, the wall of the recess 105r, the active channel sheets 110, the inner spacers 120, the first spacers 130, the dummy gate structures DG, the second spacers 165. The doped film F1 has a thickness of 1 nm. Although not illustrated, a cap film may be formed over the doped film F1, and the cap film has a thickness of 2 nm.

As illustrated in FIGS. 5E_a to 5E_b, the structure in FIGS. 5D_a and 5D_b may be heated to make the dopant thermally driven into the layers (for example, the substrate 105, the wall of the recess 105r, the active channel sheets 110, the inner spacers 120, the first spacers 130, the dummy gate structures DG, the second spacers 165) which are covered by the doped film F1 to form the doping layer 212 in these layers. The heating process include, for example, annealing (for example, flash annealing), RTA (rapid thermal annealing), etc.

As illustrated in FIGS. 5F_a to 5F_b, the doped film F1 in FIGS. 5E_a to 5E_b is removed by, for example, etching, etc. to expose these layers (for example, the substrate 105, the OD regions 1051, the wall of the recess 105r, the active channel sheets 110, the inner spacers 120, the first spacers 130, the dummy gate structures DG, the second spacers 165) which by the doped film F1 in FIGS. 5E_a and 5E_b. In addition, due to the oxide layer 107 being covered by the liner 175 and the second spacers 165, the oxide layer 107 and the second spacers 165 may be prevented from being damaged when the doped film F1 (also includes oxide material) is removed. Then, the epitaxial silicon 108 may be formed within the recess 105r by, for example, epitaxy process, etc. Then, the isolation layer 125 over the epitaxial silicon 108 by using, for example, deposition, exposure, etching, development, etc.

As illustrated in FIGS. 5G_a to 5G_b, the epitaxies 150 may be formed over the isolation layer 125. The isolation layer 125 between the epitaxy 150 and the epitaxial silicon 108 (or the substrate 105) may increase the isolation between the adjacent two of the epitaxies 150. Due to the end portion of the active channel sheet is not required to be removed, the robust and uniform source/drain (epitaxies 150) dopant coverage across sheet width and across sheets may be obtained.

As illustrated in FIGS. 5H_a to 5H_b, the CESL material 155′ over the first spacers 130, the epitaxies 150, the second spacers 165 and upper surfaces of the dummy gate structures DG are formed by using, for example, deposition, such as CVD, PECVD, ALD, or the like. The CESL material 155′ may be formed of a material including, for example, a dielectric material, such as silicon nitride, silicon oxide, silicon oxynitride, or the like.

As illustrated in FIGS. 5I_a to 5I_b, the ILD 170 covering the CESL material 155′ is formed by using, for example, deposition, such as CVD, PECVD, or FCVD, or the like. The ILD 170 may be formed of a dielectric including, for example, PSG, BSG, BPSG, USG, or the like. Other insulation materials formed by any acceptable process may be used.

As illustrated in FIGS. 5J_a to 5J_b, the ILD 170, the CESL material 155′ and the dummy gate structures DG may be planarized by using, for example, CMP. After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layer DG, the first-sub spacer portion 131, the second-sub spacer portion 132 and the ILD 170 may form, for example, a planarized surface.

As illustrated in FIGS. 5K_a to 5K_b, the SiGe layers 111 and the dummy dielectric layer DG1 and the dummy gate layer DG2 of the dummy gate structure DG may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the SiGe layers 111 also be removed by using, for example, etching. After the dummy gate structures DG and the SiGe layers 111 are removed, the active channel sheets 110 are exposed.

As illustrated in FIGS. 5L_a to 5L_b, the first dielectric layers 135 are formed on the active channel sheets 110 by using, for example, deposition. Then, the second dielectric layer 140 over the inner spacer 120 and the first dielectric layers 135 are formed by using, for example, deposition. Then, the metal gate 115 over the second dielectric layer 140 and the first spacer 130 is formed by a process such as ALD, CVD, PVD, RPCVD, PECVD, MOCVD, sputtering, electroplating, other suitable processes, or the like.

As illustrated in FIGS. 5M_a to 5M_b, a portion of the ILD 170 and a bottom portion of the CESL 155 are removed to expose the epitaxies 150 by using, for example, deposition, exposure, etching, development, etc. Then, the silicide layers 145 over the exposed epitaxies 150 are formed by using, for example, deposition.

Then, the contacts 160 in FIGS. 2_a and 2_a are formed over the CESL 155 and the epitaxies 150 in FIGS. 5M_a to 5M_b to form at least one semiconductor structure 200 as illustrated in FIGS. 2_a and 2_b. The contacts 160 may be formed of a metal including the material the same as or similar to that of the metal gate 115.

In another embodiment, the doping layer 212 in FIGS. 2_a and 2_b may be formed by using, for example, the plasma implant. Furthermore, after step of FIGS. 5C_a and 5C_b, the doping layer 212 (as illustrated in FIGS. 5E_a and 5E_b) may be formed by the plasma implant. In this example, the formation of the doped film F1 (as illustrated in FIG. 5D_a and 5D_b) and the heating process (as illustrated in FIGS. 5E_a and 5E_b) may be omitted. In this example, other manufacturing steps may be the same as or similar to the corresponding manufacturing steps of the semiconductor structure 200, and they will not be repeated here.

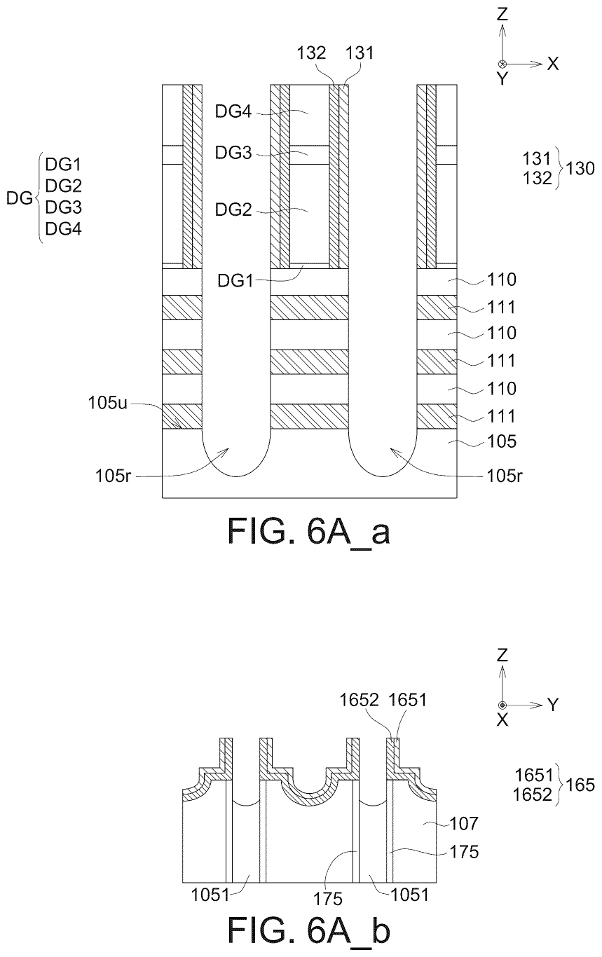

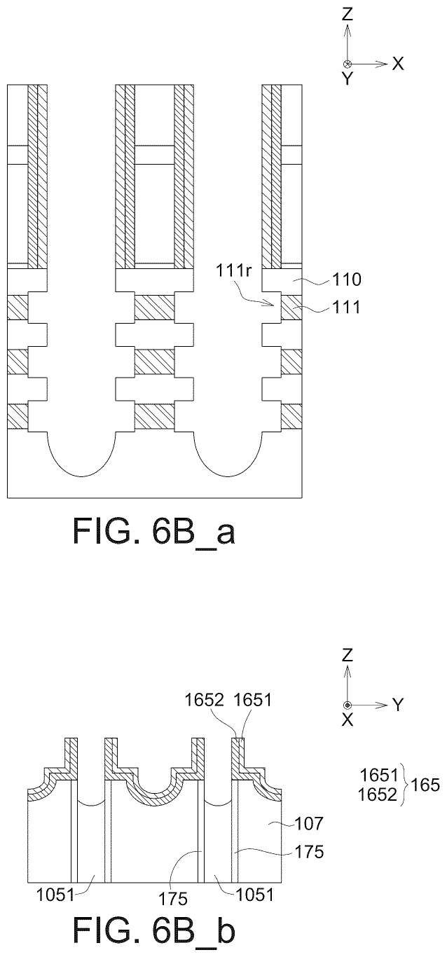

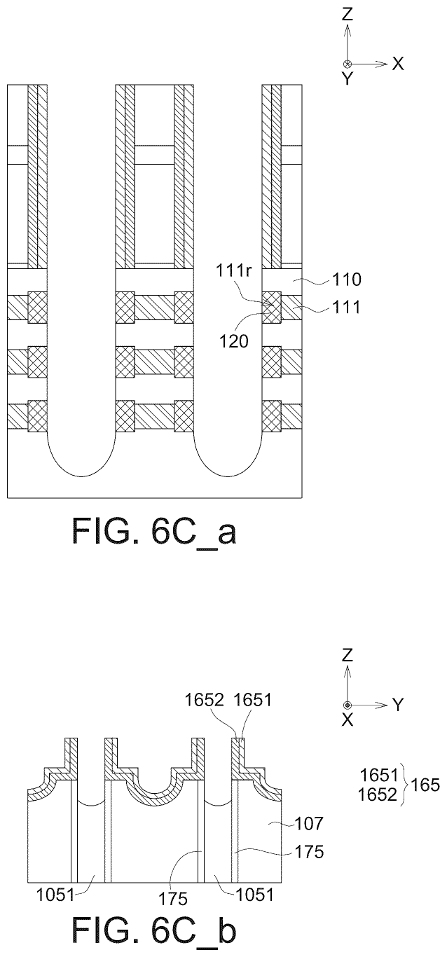

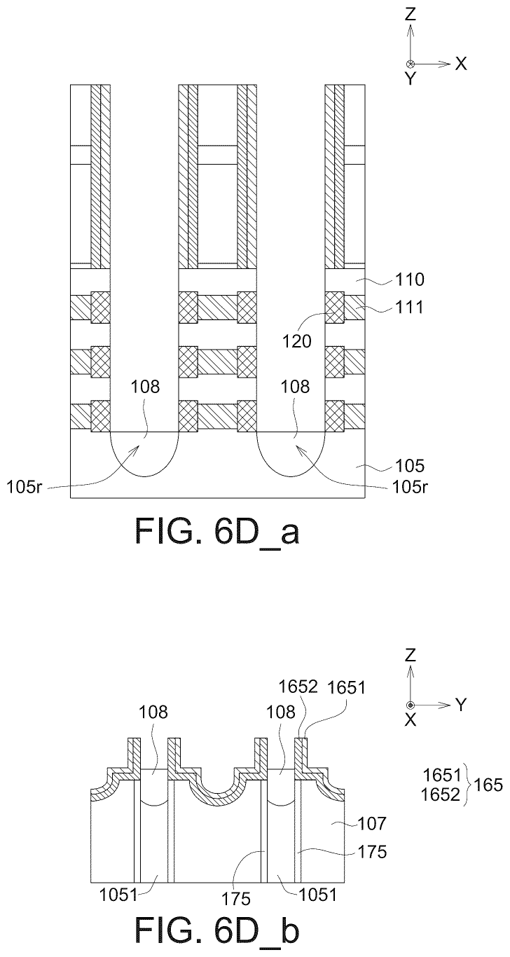

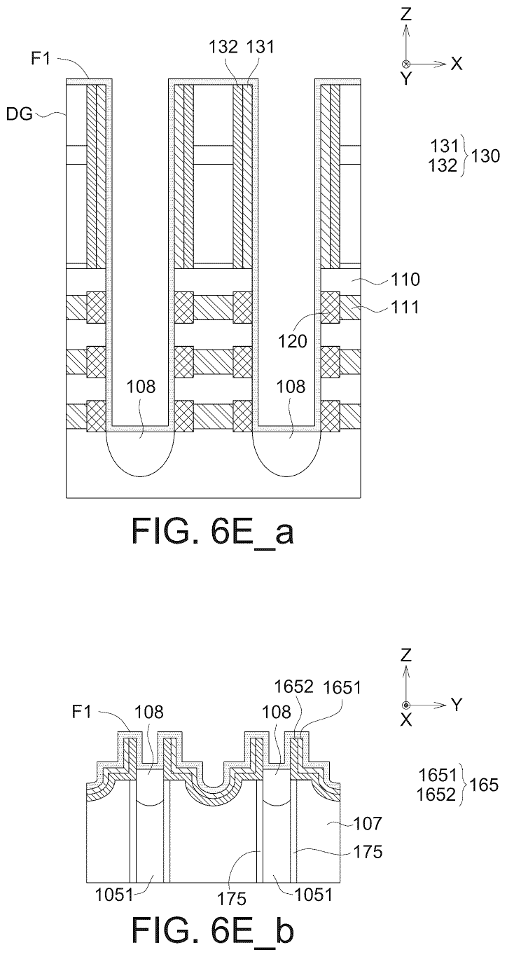

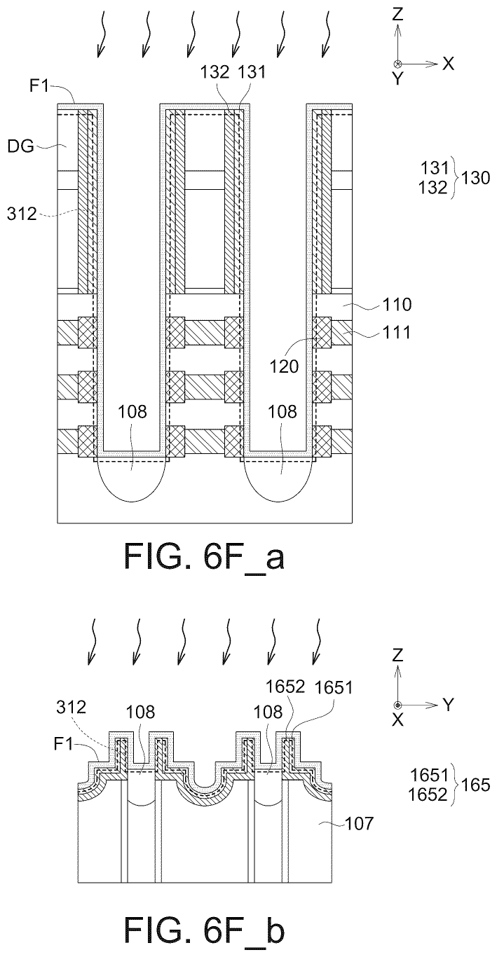

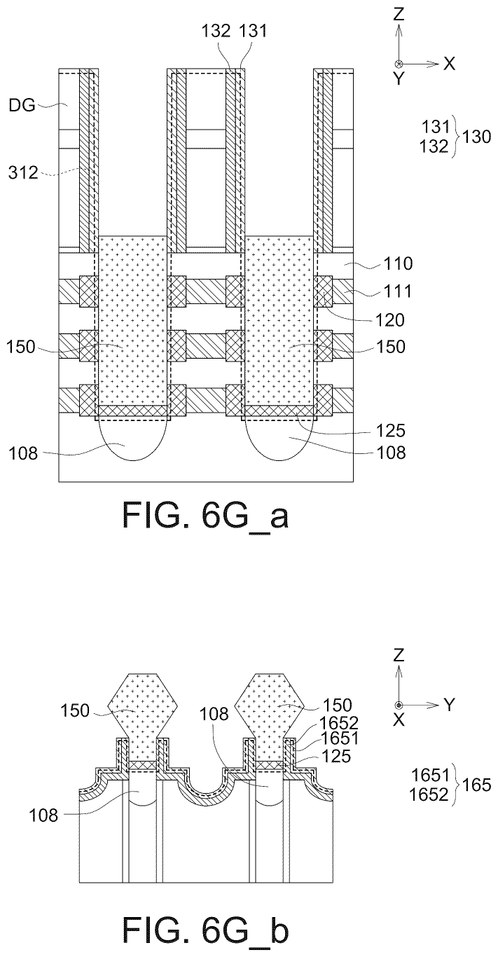

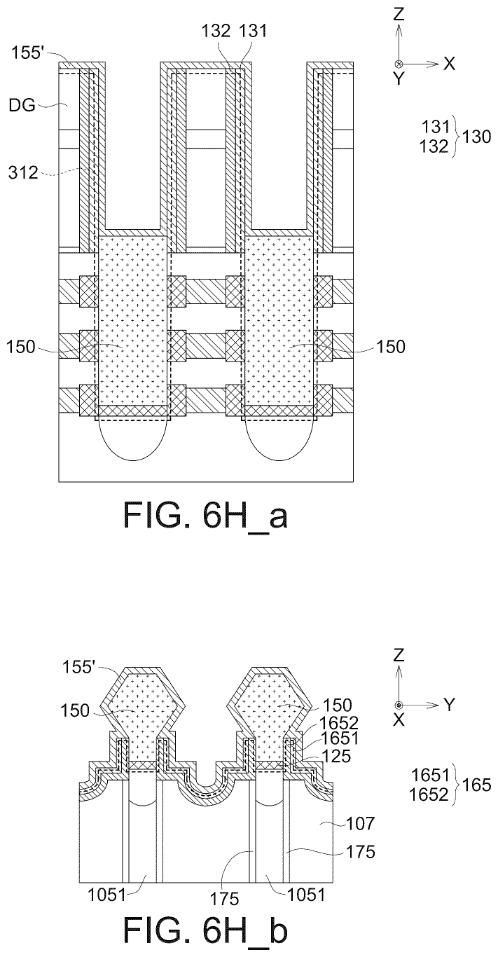

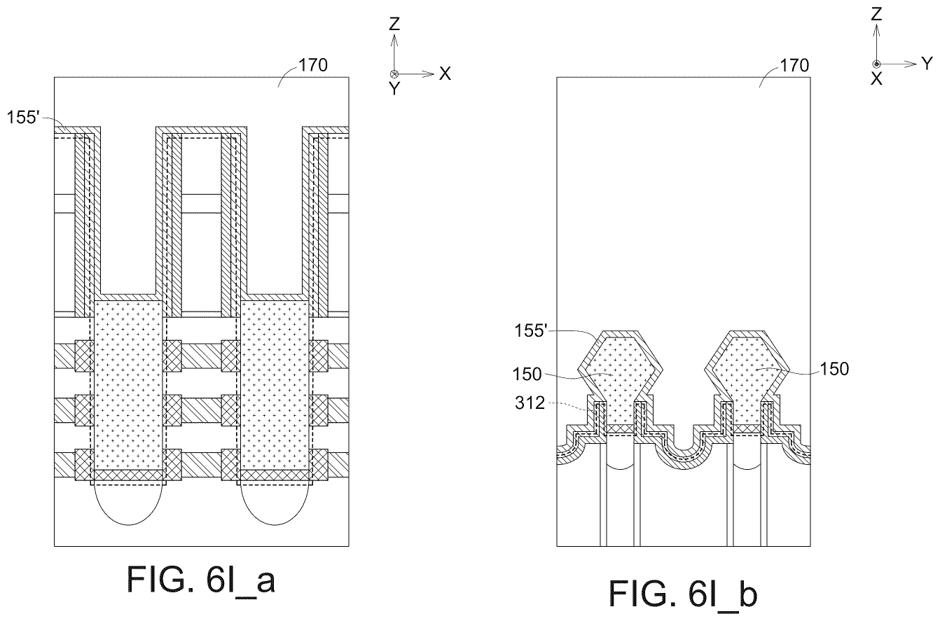

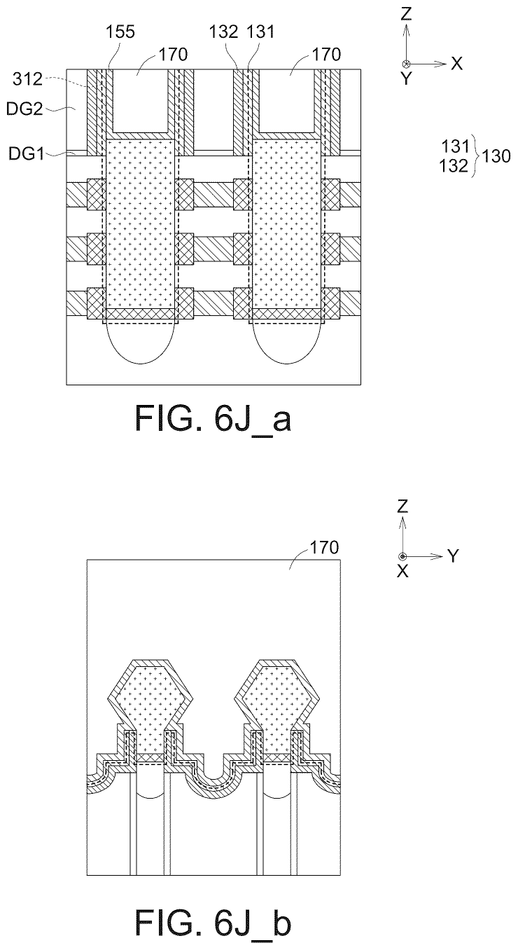

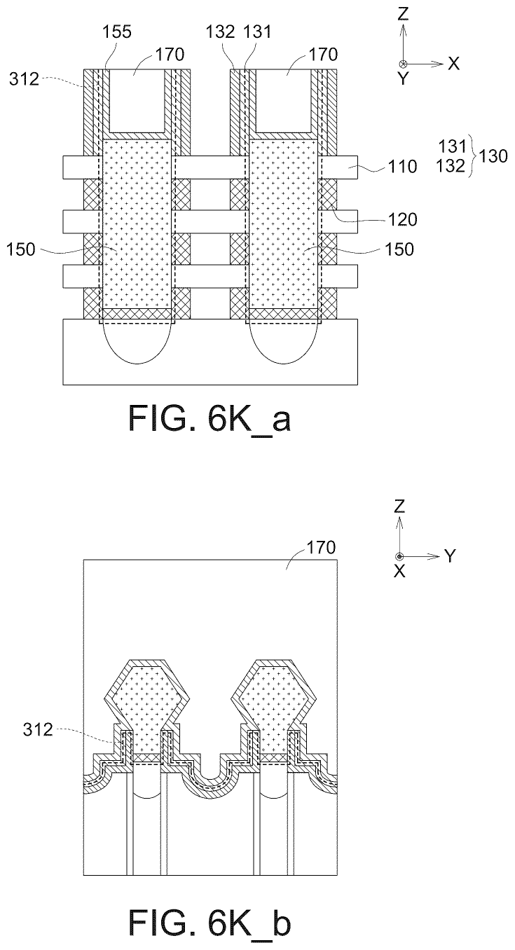

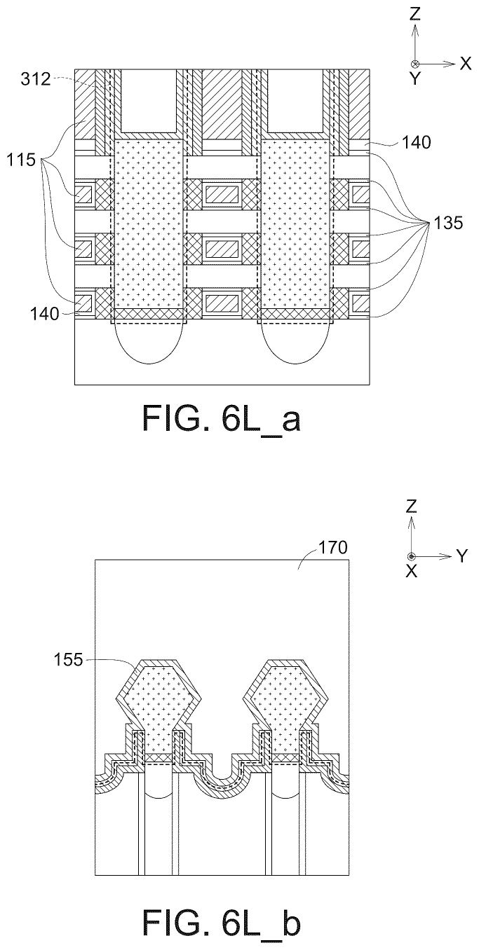

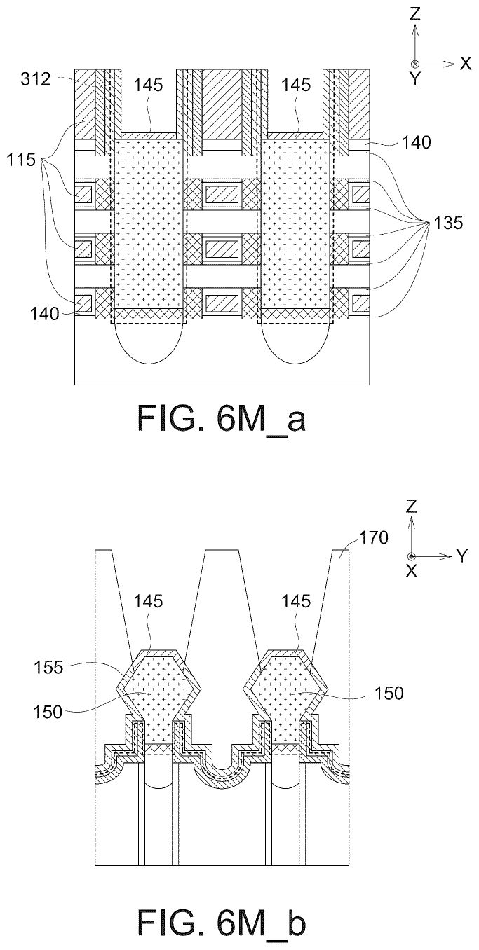

FIGS. 6A_a to 6M_b illustrate schematic diagrams of manufacturing processes of the semiconductor structure 300 in FIGS. 3_a to 3_b.

As illustrated in FIGS. 6A_a to 6A_b, a plurality of the active channel sheet 110 and a plurality of SiGe layers 111 are stacked on the substrate 105. Each active channel sheet 110 is formed of, for example, silicon. One of the active channel sheets 110 may be formed between adjacent two of the SiGe layers 111. In addition, the substrate 105 has the upper surface 105u and the recess 105r recessed relative to the upper surface 105u. In another embodiment, the second spacers 165 may not cover the recesses of the oxide layer 107, and thus the subsequent doped film F1 (in FIG. 6E_b) may be formed on the sidewalls of the recesses of the oxide layer 107, and the doping layer 312 (in FIG. 6F_b) may be formed within the sidewalls of the recesses of the oxide layer 107.

The dummy gate structures DG are formed on the active channel sheets 110 by depositing, and then the first spacer 130 is formed on adjacent two sides of the corresponding dummy gate structure DG. The first spacer 130 includes the first-sub spacer portion 131 and the second-sub spacer portion 132, wherein the second-sub spacer portion 132 is disposed between the dummy gate structures DG and the first-sub spacer portion 131. In an embodiment, the first-sub spacer portion 131 may be formed of a material different from that of the second-sub spacer portion 132. The first-sub spacer portion 131 may be formed of one of SiO, SiN, SiOC, SiON, SiOCN, etc., the second-sub spacer portion 132 may be formed of another of SiO, SiN, SiOC, SiON, SiOCN, etc.

The dummy gate structure DG includes a dummy dielectric layer DG1, a dummy gate layer DG2, a mask layer DG3 and an oxide layer DG4. The dummy dielectric layer DG1 is formed on the fin structures. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by physical vapor deposition (PVD), CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

In FIG. 6A_b, the substrate 105 includes a plurality of the OD regions 1051 extending in X-axis. The oxide layer 107 on the adjacent two sides of the OD regions 1051 is formed by using, for example, deposition. The liner 175 is formed between the OD region 1051 and the interlayer dielectric 170. The liner 175 covers a lateral surface of the interlayer dielectric 170 to protect the interlayer dielectric 170. The oxide layer 107 is, for example, a STI. The second spacers 165 are formed over the oxide layer 107. The second spacer 165 includes the first-sub spacer portion 1651 and the second-sub spacer portion 1652. The first-sub spacer portion 1651 may be formed of a material different from that of the second-sub spacer portion 1652. In terms of material, the first-sub spacer portion 1651 may be formed of one of SiO, SiN, SiOC, SiON, SiOCN, etc., and the second-sub spacer portion 1652 may be formed of another of SiO, SiN, SiOC, SiON, SiOCN, etc.

In an embodiment, the second-sub spacer portion 132 and the second-sub spacer portion 1652 may be formed in the same deposition process, and the first-sub spacer portion 131 and the first-sub spacer portion 1651 may be formed in the same deposition process. The first-sub spacer portion 131 may be formed of a material same as that of the first-sub spacer portion 1651, and the second-sub spacer portion 132 may be formed a material same as that of the second-sub spacer portion 1652. In an embodiment, the first-sub spacer portion 131 and the first-sub spacer portion 1651 may be formed in the same manufacture process (for example, deposition, etc.), and the second-sub spacer portion 132 and the second-sub spacer portion 1652 may be formed in the same manufacture process (for example, deposition, etc.).

As illustrated in FIGS. 6B_a to 6B_b, a plurality of the recesses 111r in the SiGe layers 111 are formed by using, for example, etching. The recess 111r is recessed relative to the lateral surface 111s of the active channel sheet 110.

As illustrated in FIGS. 6C_a to 6C_b, the inner spacers 120 are formed within the recesses 111r by deposition, etching, etc.

As illustrated in FIGS. 6D_a to 6D_b, the epitaxial silicon 108 may be formed within the recess 105r by, for example, epitaxy process, etc.

As illustrated in FIGS. 6E_a to 6E_b, the doped film F1 with high concentration, for example, the BSG film or the PSG film is formed by, for example, deposition. In an embodiment, the doped film F1 is a solid-solid-phase film (for example, dopant glass film). The BSG film has the boron concentration of 2×10¹⁹cm⁻³¿5×10²¹cm⁻³, and the PSG film has the phosphorus concentration of 2×10¹⁹cm⁻³¿5×10²¹cm⁻³. The doped film F1 cover outer surfaces of the substrate 105, the epitaxial silicon 108, the active channel sheets 110, the inner spacers 120, the first spacers 130, the dummy gate structures DG, the second spacers 165. The doped film F1 has a thickness of 1 nm. Although not illustrated, a cap film may be formed over the doped film F1, and the cap film has a thickness of 2 nm.

As illustrated in FIGS. 6F_a to 6F_b, the structure in FIGS. 6E_a and 6E_b may be heated to make the dopant thermally driven into the layers (for example, the substrate 105, the wall of the recess 105r, the epitaxial silicon 108, the active channel sheets 110, the inner spacers 120, the first spacers 130, the dummy gate structures DG and the second spacers 165) which are covered by the doped film F1 to form the doping layer 312 in these layers. The heating process include, for example, annealing (for example, flash annealing), RTA (rapid thermal annealing), etc.

As illustrated in FIGS. 6G_a to 6G_b, the doped film F1 in FIGS. 6F_a to 6F_b is removed by, for example, etching, etc. to expose these layers (for example, the substrate 105, the epitaxial silicon 108, the active channel sheets 110, the inner spacers 120, the first spacers 130, the dummy gate structures DG, the second spacers 165) which by the doped film F1 in FIGS. 6F_a and 6F_b. In addition, due to the oxide layer 107 being covered by the liner 175 and the second spacers 165, the oxide layer 107 and the second spacers 165 may be prevented from being damaged when the doped film F1 (also includes oxide material) is removed. Then, the isolation layer 125 over the epitaxial silicon 108 by using, for example, deposition, exposure, etching, development, etc. Then, the epitaxies 150 may be formed over the isolation layer 125. The isolation layer 125 between the epitaxy 150 and the epitaxial silicon 108 (or the substrate 105) may increase the isolation between the adjacent two of the epitaxies 150. Due to the end portion of the active channel sheet is not required to be removed, the robust and uniform source/drain (epitaxies 150) dopant coverage across sheet width and across sheets may be obtained.

As illustrated in FIGS. 6H_a to 6H_b, the CESL material 155′ over the first spacers 130, the epitaxies 150, the second spacers 165 and upper surfaces of the dummy gate structures DG are formed by using, for example, deposition, such as CVD, PECVD, ALD, or the like. The CESL material 155′ may be formed of a material including, for example, a dielectric material, such as silicon nitride, silicon oxide, silicon oxynitride, or the like.

As illustrated in FIGS. 6I_a to 6I_b, the ILD 170 covering the CESL material 155′ is formed by using, for example, deposition, such as CVD, PECVD, or FCVD, or the like. The ILD 170 may be formed of a dielectric including, for example, PSG, BSG, BPSG, USG, or the like. Other insulation materials formed by any acceptable process may be used.

As illustrated in FIGS. 6J_a to 6J_b, the ILD 170, the CESL material 155′ and the dummy gate structures DG may be planarized by using, for example, CMP. After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layer DG, the first-sub spacer portion 131, the second-sub spacer portion 132 and the ILD 170 may form, for example, a planarized surface.

As illustrated in FIGS. 6K_a to 6K_b, the SiGe layers 111 and the dummy dielectric layer DG1 and the dummy gate layer DG2 of the dummy gate structure DG may be removed by using, for example, an anisotropic dry etch process. Furthermore, the etching process could include a dry etch process using reaction gas(es) that selectively etch the dummy gate structures DG at a faster rate than the ILD 170. In an embodiment, before the removal, a helmet (not illustrated) may be formed on the ILD 170, by using for example, etching/deposition, to block the removal for the dummy gate structures DG. In addition, the SiGe layers 111 also be removed by using, for example, etching. After the dummy gate structures DG and the SiGe layers 111 are removed, the active channel sheets 110 are exposed.

As illustrated in FIGS. 6L_a to 6L_b, the first dielectric layers 135 are formed on the active channel sheets 110 by using, for example, deposition. Then, the second dielectric layer 140 over the inner spacer 120 and the first dielectric layers 135 are formed by using, for example, deposition. Then, the metal gate 115 over the second dielectric layer 140 and the first spacer 130 is formed by a process such as ALD, CVD, PVD, RPCVD, PECVD, MOCVD, sputtering, electroplating, other suitable processes, or the like.

As illustrated in FIGS. 6M_a to 6M_b, a portion of the ILD 170 and a bottom portion of the CESL 155 are removed to expose the epitaxies 150 by using, for example, deposition, exposure, etching, development, etc. Then, the silicide layers 145 over the exposed epitaxies 150 are formed by using, for example, deposition.

Then, the contacts 160 in FIGS. 3_a and 3_a are formed over the CESL 155 and the epitaxies 150 in FIGS. 6M_a to 6M_b to form at least one semiconductor structure 300 as illustrated in FIGS. 3_a and 3_b. The contacts 160 may be formed of a metal including the material the same as or similar to that of the metal gate 115.

In another embodiment, the doping layer 312 in FIGS. 3_a and 3_b may be formed by using, for example, the plasma implant. Furthermore, after step of FIGS. 6D_a and 6D_b, the doping layer 312 (as illustrated in FIGS. 6F_a and 6F_b) may be formed by the plasma implant. In this example, the formation of the doped film F1 (as illustrated in FIGS. 6E_a and 6E_b) and the heating process (as illustrated in FIGS. 6F_a and 6F_b) may be omitted. In this example, other manufacturing steps may be the same as or similar to the corresponding manufacturing steps of the semiconductor structure 300, and they will not be repeated here.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure at least includes an active channel sheet and a doping layer. The doping layer is disposed within the active channel sheet. The doping layer may be formed by a doped film with high concentration, for example, a BSG film or a PSG film. In the present embodiment, the end portion of the active channel sheet is not required to be removed for filling epitaxial material, the channel length of the active channel sheet may be maintained, and thus the current leakage may be effectively avoided. In addition, due to the doped film is formed by the doped film, an edge region of the doping layer adjacent to the inner spacer has a doping concentration higher than that of a center region of the doping layer, and thus the gate may be better controlled.

Example embodiment 1: a semiconductor structure includes a substrate, an active channel sheet and a doping layer. The active channel sheet stacked on the substrate, wherein the active channel sheet has an end portion having a lateral surface, an upper surface and a lower surface. The doping layer is disposed within the end portion of the active channel sheet. The doping layer has a contour having an upper point adjacent to the upper surface, a lower point adjacent to the lower surface and a middle point between the upper point and the lower point, there is an upper distance between the upper point and the lateral surface, there is a lower distance between the lower point and the lateral surface, there is a middle distance between the middle point and the lateral surface, and the upper distance and the lower distance are less than the middle distance.

Example embodiment 2 based on Example embodiment 1: the semiconductor structure further includes a metal gate and an inner spacer. The metal gate is disposed on the active channel sheet. The inner spacer is disposed on a lateral surface of the metal gate. The doping layer is disposed within the inner spacer.

Example embodiment 3 based on Example embodiment 1: there is a contour distance between the contour and the lateral surface of the active channel sheet, the contour distance gradually decreases from the upper surface toward the middle point between the upper surface and the lower surface, and gradually increase from the middle point toward the lower surface.

Example embodiment 4 based on Example embodiment 1: the semiconductor structure further includes a metal gate and a first spacer. The metal gate is disposed on the active channel sheet. The first spacer covers a sidewall of the metal gate. The doping layer is disposed within the first spacer.

Example embodiment 5 based on Example embodiment 1: the substrate has an upper surface and a recess recessed relative to the upper surface, and the doping layer is disposed within a wall of the recess.

Example embodiment 6 based on Example embodiment 1: the substrate has an upper surface and a recess recessed relative to the upper surface. The semiconductor structure further includes a silicon epitaxy within the recess. The doping layer is disposed within a wall of the silicon epitaxy.

Example embodiment 7 based on Example embodiment 1: the substrate includes an oxide definition (OD) region having a lateral surface, and further includes an oxide layer and a liner. The liner is disposed between the lateral surface of the OD region and the oxide layer.

Example embodiment 8 based on Example embodiment 1: the doping layer is a boron doping layer or a phosphorus doping layer.

Example embodiment 9: a semiconductor structure includes a substrate, an active channel sheet and a doping layer. The active channel sheet is stacked on the substrate, wherein the active channel sheet has an end portion having a lateral surface, an upper surface and a lower surface. The doping layer is disposed within the end portion of the active channel sheet and having a concentration distribution. The concentration distribution gradually decreases from the upper surface toward a middle point between the upper surface and the lower surface, and gradually increases from the middle toward the lower surface.

Example embodiment 10 based on Example embodiment 9: the semiconductor structure further includes a metal gate and an inner spacer. The metal gate is disposed on the active channel sheet. The inner spacer is disposed on a lateral surface of the metal gate. The doping layer is disposed within the inner spacer.

Example embodiment 11 based on Example embodiment 9: there is a contour distance between the contour and the lateral surface of the active channel sheet, the contour distance gradually decreases from the upper surface to the middle point, and gradually increase from the middle point to the lower surface.

Example embodiment 12 based on Example embodiment 9: the semiconductor structure further includes a metal gate and a first spacer. The metal gate is disposed on the active channel sheet. The first spacer covers a sidewall of the metal gate. The doping layer is disposed within the first spacer.

Example embodiment 13 based on Example embodiment 9: the substrate has an upper surface and a recess recessed relative to the upper surface, and the doping layer is disposed within a wall of the recess.

Example embodiment 14 based on Example embodiment 10: the substrate has an upper surface and a recess recessed relative to the upper surface. The semiconductor structure further includes a silicon epitaxy within the recess. The doping layer is disposed within a wall of the silicon epitaxy.

Example embodiment 15 based on Example embodiment 9: the substrate includes an OD region having a lateral surface, and further includes an oxide layer and a liner. The liner is disposed between the lateral surface of the OD region and the oxide layer.

Example embodiment 16 based on Example embodiment 9: the doping layer is a boron doping layer or a phosphorus doping layer.

Example embodiment 17: a manufacturing method for a semiconductor structure includes the following steps: forming an active channel sheet and a silicon germanium (SiGe) layer on a substrate, wherein the active channel sheet includes an end portion having a lateral surface, an upper surface and a lower surface; forming a doped film over the active channel sheet and the SiGe layer; heating the doped film to form a doping layer, wherein the doping layer has a contour having an upper point adjacent to the upper surface, a lower point adjacent to the lower surface and a middle point between the upper point and the lower point, there is an upper distance between the upper point and the lateral surface, there is a lower distance between the lower point and the lateral surface, there is a middle distance between the middle point and the lateral surface, and the upper distance and the lower distance are less than the middle distance; and removing the doped film to expose the active channel sheet and the SiGe layer.

Example embodiment 18 based on Example embodiment 17: the substrate has an upper surface and a recess recessed relative to the upper surface; in forming the doped film, the doping layer further covers the recess; in heating the doped film, the doping layer is further formed within a wall of the recess.

Example embodiment 19 based on Example embodiment 17: the manufacturing method further includes: forming a recess in the SiGe layer, wherein the recess is recessed relative to the lateral surface of the active channel sheet; and forming an inner spacer within the recess. In forming the doped film, the doping layer further covers the inner spacer; in heating the doped film, the doping layer is further formed within the inner spacer.

Example embodiment 20 based on Example embodiment 17: the substrate has an upper surface and a recess recessed relative to the upper surface; the manufacturing method further includes: forming a silicon epitaxy within the recess. In forming the doped film, the doping layer further covers the silicon epitaxy; in heating the doped film, the doping layer is further formed within the silicon epitaxy.

Example embodiment 21: a manufacturing method for a semiconductor structure includes the following steps: forming an active channel sheet and a SiGe layer on a substrate, wherein the active channel sheet includes an end portion having a lateral surface, an upper surface and a lower surface; forming a doping layer by using, for example, a plasma implant.

Example embodiment 22 based on Example embodiment 21: the doping layer has a contour having an upper point adjacent to the upper surface, a lower point adjacent to the lower surface and a middle point between the upper point and the lower point, there is an upper distance between the upper point and the lateral surface, there is a lower distance between the lower point and the lateral surface, there is a middle distance between the middle point and the lateral surface, and the upper distance and the lower distance are less than the middle distance; and removing the doped film to expose the active channel sheet and the SiGe layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
an active channel sheet stacked on the substrate, wherein the active channel sheet has an end portion having a lateral surface, an upper surface and a lower surface; and
a doping layer within the end portion of the active channel sheet;
wherein the doping layer has a contour having an upper point adjacent to the upper surface, a lower point adjacent to the lower surface and a middle point between the upper point and the lower point, there is an upper distance between the upper point and the lateral surface, there is a lower distance between the lower point and the lateral surface, there is a middle distance between the middle point and the lateral surface, and the upper distance and the lower distance are less than the middle distance.

2. The semiconductor structure according to claim 1, further comprising:
a metal gate on the active channel sheet; and
an inner spacer on a lateral surface of the metal gate;
wherein the doping layer is disposed within the inner spacer.

3. The semiconductor structure according to claim 1, wherein there is a contour distance between the contour and the lateral surface of the active channel sheet, the contour distance gradually decreases from the upper surface toward the middle point between the upper surface and the lower surface, and gradually increase from the middle point toward the lower surface.

4. The semiconductor structure according to claim 1, further comprising:
a metal gate on the active channel sheet; and
a first spacer covering a sidewall of the metal gate;
wherein the doping layer is disposed within the first spacer.

5. The semiconductor structure according to claim 1, wherein the substrate has an upper surface and a recess recessed relative to the upper surface, and the doping layer is disposed within a wall of the recess.

6. The semiconductor structure according to claim 1, wherein the substrate has an upper surface and a recess recessed relative to the upper surface; the semiconductor structure further comprises:
a silicon epitaxy within the recess;
wherein the doping layer is disposed within a wall of the silicon epitaxy.

7. The semiconductor structure according to claim 1, wherein the substrate comprises an oxide definition (OD) region having a lateral surface, and further comprises:
an oxide layer; and
a liner disposed between the lateral surface of the OD region and the oxide layer.

8. The semiconductor structure according to claim 1, wherein the doping layer is a boron doping layer or a phosphorus doping layer.

9. A semiconductor structure, comprising:
a substrate;
an active channel sheet stacked on the substrate, wherein the active channel sheet has an end portion having a lateral surface, an upper surface and a lower surface;
a doping layer within the end portion of the active channel sheet and having a concentration distribution;
wherein the concentration distribution gradually decreases from the upper surface toward a middle point between the upper surface and the lower surface, and gradually increases from the middle point toward the lower surface.

10. The semiconductor structure according to claim 9, further comprising:
a metal gate on the active channel sheet; and
an inner spacer on a lateral surface of the metal gate;
wherein the doping layer is disposed within the inner spacer.

11. The semiconductor structure according to claim 9, wherein there is a contour distance between the contour and the lateral surface of the active channel sheet, the contour distance gradually decreases from the upper surface to the middle point, and gradually increase from the middle point to the lower surface.

12. The semiconductor structure according to claim 9, further comprising:
a metal gate on the active channel sheet; and
a first spacer covering a sidewall of the metal gate;
wherein the doping layer is disposed within the first spacer.

13. The semiconductor structure according to claim 9, wherein the substrate has an upper surface and a recess recessed relative to the upper surface, and the doping layer is disposed within a wall of the recess.

14. The semiconductor structure according to claim 9, wherein the substrate has an upper surface and a recess recessed relative to the upper surface; the semiconductor structure further comprises:
a silicon epitaxy within the recess;
wherein the doping layer is disposed within a wall of the silicon epitaxy.

15. The semiconductor structure according to claim 9, wherein the substrate comprises an oxide definition (OD) region having a lateral surface, and further comprises:
an oxide layer; and
a liner disposed between the lateral surface of the OD region and the oxide layer.

16. The semiconductor structure according to claim 9, wherein the doping layer is a boron doping layer or a phosphorus doping layer.

17. A manufacturing method of a semiconductor structure, comprising:
forming an active channel sheet and a silicon germanium (SiGe) layer on a substrate, wherein the active channel sheet comprises an end portion having a lateral surface, an upper surface and a lower surface;
forming a doped film over the active channel sheet and the SiGe layer;
heating the doped film to form a doping layer, wherein the doping layer has a contour having an upper point adjacent to the upper surface, a lower point adjacent to the lower surface and a middle point between the upper point and the lower point, there is an upper distance between the upper point and the lateral surface, there is a lower distance between the lower point and the lateral surface, there is a middle distance between the middle point and the lateral surface, and the upper distance and the lower distance are less than the middle distance; and
removing the doped film to expose the active channel sheet and the SiGe layer.

18. The manufacturing method according to claim 17, wherein the substrate has an upper surface and a recess recessed relative to the upper surface; in forming the doped film, the doping layer further covers the recess; in heating the doped film, the doping layer is further formed within a wall of the recess.

19. The manufacturing method according to claim 17, further comprising:
forming a recess in the SiGe layer, wherein the recess is recessed relative to the lateral surface of the active channel sheet; and
forming an inner spacer within the recess;
wherein in forming the doped film, the doping layer further covers the inner spacer; in heating the doped film, the doping layer is further formed within the inner spacer.

20. The manufacturing method according to claim 17, wherein the substrate has an upper
surface and a recess recessed relative to the upper surface; the manufacturing method further comprises:
forming a silicon epitaxy within the recess;
wherein in forming the doped film, the doping layer further covers the silicon epitaxy;
in heating the doped film, the doping layer is further formed within the silicon epitaxy.
